(19) United States
(12) Patent Application Publication
(10) Pub. No.: US 2025/0328121 A1
(43) Pub. Date: Oct. 23, 2025

(54) A DATA LOGGER

(71) Applicant: Element Engineering Australia Pty Ltd, Malaga Perth (AU)

(72) Inventor: Ayrton Bradley SUE, Karrinyup (AU)

(73) Assignee: Element Engineering Australia Pty Ltd, Malaga Perth (AU)

(21) Appl. No.: 18/845,181

(22) PCT Filed: Mar. 8, 2023
(86) PCT No.: PCT/AU2023/050158

§ 371 Date: Sep. 9, 2024

(30) Foreign Application Priority Data
Mar. 9, 2022 (AU) 2022900575

(51) Int. Cl. G05B 19/406

(52) U.S. Cl. CPC G05B 19/406

(57) ABSTRACT

A data logger comprising a sensor interface for connecting at least one sensor or actuator to the data logger; an accessible memory (SD card) for storing data received from said at least one sensor or actuator; and a controller for controlling operation of the data logger wherein said data logger comprises a plurality of modules, each module having a housing electrically and mechanically connectable to a housing of an adjacent module; and wherein at least one module comprises the sensor interface and acts as a logging and/or actuation module (LAM) including at least a portion of said accessible memory (SD card); and at least one module connected to said at least one LAM acts as a control and communications module (CCM) and comprises the controller that controls communications within and external to the data logger.

### TECHNICAL FIELD

This invention relates to a data logger and data logger system that can be used for data acquisition, conveniently for use in process control.

### BACKGROUND ART

The following discussion of the background art is intended to facilitate an understanding of the present invention only. The discussion is not an acknowledgement or admission that any of the material referred to is or was part of the common general knowledge as at the priority date of the application.

Data loggers are widely used in science and engineering for the acquisition of data, typically to be used in process control. Data is acquired from one, or a plurality of, sensor(s) which are connected to the data logger, typically through cables though wireless implementations are known.

Data loggers may be general purpose type or designed for very specific applications. Those designed for specific applications are typically customised, potentially following an intensive process control design process. Such data loggers can be expensive and are not directed at the hobbyist or simple control applications, for example for business application. Price makes such accessibility unfeasible.

General purpose data loggers may, in principle, be applied to a range of measurement and control applications: see, for example, en.wikipedia.org/wiki/Data_logger. A general-purpose data logger is commonly programmable but typically with only a limited number of, or no, changeable parameters. Again, such data loggers may be relatively expensive. Again, accessibility issues arise. Less expensive data loggers may also have less programming flexibility.

Slow network speeds also tend to hinder operation of data loggers dependent on streaming of data.

It would be advantageous to provide a more flexible data logger for data acquisition, in particular for use in process control.

### SUMMARY OF INVENTION

In one aspect, the present invention provides a sensor interface for connecting at least one sensor or actuator to the data logger;
an accessible memory for storing data received from said at least one sensor or actuator; and
a controller for controlling operation of the data logger
   wherein said data logger comprises a plurality of modules, each module having a housing electrically and mechanically connectable to a housing of an adjacent module; and
   wherein at least one module comprises the sensor interface and acts as a logging and/or actuation module (LAM) including at least a portion of said accessible memory; and at least one module connected to said at least one LAM acts as a control and communications module (CCM) and comprises the controller that controls communications within and external to the data logger.

A logging and/or actuation module (LAM) may communicate with at least one further LAM to form a stack of LAMs. Modularity of the data logger enables flexibility in providing the required number of sensors and actuators for, for example, a process control system. A stack of LAM, and optionally CCM, may be co-located allowing the stack to be formed within the same footprint available for location of the data logger. The stack of modules may be located within an enclosure with standard industrial types potentially being useful for this. Other arrangements are also possible. For example, a LAM may be ‘daisy chained’ to at least one further LAM though this may have limitations due to available data communication speeds through the network.

LAMs of the same or different data loggers may conveniently be networked by way of serial communications over a wireless network. Serial communications may be provided by a protocol selected from the group consisting of a short range protocol (preferably Bluetooth), a long range protocol (preferably LoRA) and TCP/IP. Serial communications are advantageously possible with a range of user devices including from the group consisting of a mobile phone, smartphone, tablet, portable and a computing device.

The controller for controlling operation of the data logger preferably includes a microcontroller though a microprocessor could be used in some applications. Preferably, the controller module also enables control over communications and, in this case, is further referred to as a control and communications module (CCM). Conveniently, a communications bus-preferably a CAN communications bus is included to allow communication between the CCM and LAM(s), devices within the CCM and LAM(s) and user devices. Alternatively to CAN communications, proprietary communication protocols can be developed by a user. An alternative differential pair signalling system, such as RS 485 communications may also be used. RS 485 is electrically very similar to CAN, using a differential twisted pair of wires operating in the 0-5 volt range. It may be necessary, with alternatives to CAN, to address collisions of information on the electrical bus with software algorithms.

Conveniently, a LAM or CCM is provided with at least one user configurable input and at least one user configurable output. For example, a button (input) and indicator (output), with LEDs being preferred, may be configured to a specific use selected by the user of the data logger. The LAM may, for example, conveniently allow single button operation allowing a user of the data logger to select modes of LAM operation, this providing an easy to use module that is conveniently usable for hobby applications as well as professional applications. User selected modes of LAM operation could include, without limitation: a sleep state, a logging state or an output actuator such as an alarm indicating that a sensed signal is outside permissible bounds, e.g. a sensed pressure has exceeded a threshold for actuating the alarm. An indicator output could visually indicate an alarm or selected process state. In the case where the controller includes logic in the form, for example, of a state machine with the data logger monitoring transitions between states, pushing the button may provide the transition from one state to another. The button could thus allow transition from an automatic control to a manual control mode.

The CCM may include one or a plurality of internal and/or external antenna(s) to allow wireless communication through protocols such as those described above. Optionally, antennas and/or antenna arrangements may be configured to meet a MIMO standard. Conveniently, a wide band antenna is included allowing accommodation of a number of possible wireless communications protocols. Such an antenna is desirably mounted internally of the data logger. Standard wireless antennae corresponding with particular wireless communications networks may be provided in other embodiments.

The data logger may advantageously store data on board in the accessible memory, for an example a USB drive or an SD card which may form at least part of accessible memory. Without limitation on the memory storage devices selected, accessible memory may include a plurality of memory storage devices, a port being provided for each memory storage device within each LAM of the data logger. Accessible memory may also include non-externally accessible storage, optionally flash storage on a circuit board included within a module, data being retrievable from said non-externally accessible storage by wireless communication.

Alternatively, or additionally, the data logger can accommodate streaming of data through a wired or wireless network including through cloud computing. However, streaming has limitations, one of which is that maximum data throughput for sensed signals through a network may not be fast enough to keep up with the signals being processed (and so not real time). Latency and delay in sending sensor signals may also be an issue. Preferably, therefore, accessible memory for storing sensor and actuator signals (for later processing or transformation) is provided within the data logger. So, for example, data can be stored to memory storage devices including, for example, a USB device (allowing a wired connection to a computer) or memory cards such as a removable SD card, SDHC card, Micro SDXC card or flash card. Such memory storage devices can be retrieved to allow data download, conveniently for a selected specific time period of data acquisition, without interfering with a communications network though wireless communication is an available option.

The data logger—and more particularly LAM(s) of the data logger—may be provided with one or more ports allowing flexibility in selection of memory storage devices providing accessible memory. For example, a LAM may be provided with ports for USB device and SD card both of which allow storage of data and transfer of data. A microcontroller included within each LAM of the data logger can also process signals on board the data logger allowing it to operate on a standalone basis. An additional microprocessor can be included in some applications, for example to transform large volumes of data with a microprocessor typically having the advantage of large amounts of external RAM and allowing larger volumes of calculations without impacting on its real time operations.

Alternatively, or additionally, memory can be made available externally of the data logger with communication of data to an external memory storage device being possible through use of a convenient wired or wireless communications protocol, including TCP/IP, short range (preferably Bluetooth (BLE)), long range protocol (preferably LORA or RF), Websocket and/or Ethernet. The data logger may communicate with an external communication device, i.e. a networked device, whether a computer system (including a cloud-based server); or a laptop, a smartphone, a smart device or an IoT device, the latter group conveniently including user devices and allowing a user to configure the system while mobile or in a fixed position.

A microcontroller is desirably included within each LAM of the data logger to process signals on board the data logger. Signals from at least one sensor or actuator may conveniently be processed using transformations determined by a user of the data logger.

The data logger may be configured with logic in the form of state machines and corresponding transformations in a number of ways. For example, the data logger may be configured by a script loaded onto at least one said memory storage device. The data logger may additionally, or alternatively, be remotely configured through a script downloaded to the accessible memory by a web based user interface or mobile app.

The data logger is typically provided with a power supply, for example an industrial power supply (conveniently a 9 to 30 volt industrial power supply), though a range of power supply options are available if such an industrial power supply (or other power supply) is not available. The data logger may derive power from a plurality of power supply options including as selected by the controller, preferably automatically. Such power supply options would typically include an auxiliary power module, conveniently having the same form factor as a LAM described above. A plurality of auxiliary power modules may be included as required. Another power supply option could be Power over Ethernet (POE) or a similar standard (including under IEEE Standard 802.3) that enables data and power to be transferred simultaneously, for example through a twisted pair cable. A PoE module could act as CCM though may be provided as a LAM.

The controller may select a highest available power supply for supply to the data logger. For example, where multiple auxiliary power modules are used, the CCM may enable negotiation between the multiple auxiliary power modules via the above described serial communications with LAM(s) to determine which auxiliary power module(s) provide power to the data logger.

A further power supply option may include battery operation with an auxiliary power module including rechargeable batteries. Such an auxiliary power module may, for example, receive power from an energy harvesting system (such as a solar power system) and battery management system which is conveniently connected to the data logger. Auxiliary power modules are particularly desirable to provide resilience to power outages.

Power is distributed from the power supply to the CCM and LAMs through power rails to enable operation of the data logger. In one embodiment, such power rails may include a Vraw power rail for providing the highest available power supply available to the data logger whether from an industrial power supply or an auxiliary power module as described above. The Vraw power rail may supply power to an auxiliary power module, for example to recharge batteries where battery power is used.

Voltage is regulated from the power supply to the data logger and its components as required. The data logger may be provided with an uninterruptable power supply (UPS) capability where an auxiliary power module is included. To that end, the data logger may conveniently be configured with controller and power rail(s) to allow transition from a preferred power supply, for example an industrial supply, to the auxiliary power supply, for example a battery pack.

Data acquired by the data logger may be processed using software, conveniently web hosted software, that allows the user to configure the data logger, conveniently through a web based user interface or mobile app, and customise data processing to the data logger system they have constructed, for example for use in process control. Alternatively, a user may process acquired data within their own software, whether proprietary or ‘off the shelf’, for example through the Office 365® platform. Data processing software may be downloaded from a server providing the user with the functionality to process data locally.

A LAM, or CCM, preferably allows a waterproof and dustproof connection of each sensor or actuator cable or wire to a respective port of the data logger. An IP67 and preferably an IP68 rating is achievable by the data logger. In such case, the at least one sensor or actuator is connected to a housing of the data logger with a connection providing at least an IP67 rating, preferably an IP68 rating, for the data logger. In such embodiments, at least one sensor or actuator is connected to a housing comprised within the data logger by a clamping seal for a sensor or actuator cable, said seal sealing ingress along a path of said cable and forming a clamp preventing said cable being pulled out of the housing. The clamping seal may be provided within a wall of said housing, optionally by pinching of the sensor or actuator cable.

A suitable clamp may comprise a tubular sealing sleeve extending into a port which accommodates the sensor or actuator cable, the sleeve being provided with sealing means to seal the cable at the sleeve and at the port. Conveniently, the sealing means is a double lip seal. A suitable clamp enables said sleeve and sensor or actuator cable to be clamped into the correct position at the port using a clamping seal. The clamping means may exert a pinching action on the cable as it exits the sleeve inward of the port. The clamping means may be a wedge with a slot for engaging the cable, said wedge engaging with said tubular sleeve, said wedge also having an angled back face which, when wedged into position, forms a seal against an inside face of said wall of the housing.

Other embodiments, potentially useful for environments in which sealing is not required, allow standard or ‘off the shelf’ cable connectors to be used with the data logger. A combination of clamping seal connectors, as above described, and standard connectors may be used.

The data logger is suitable for use in process control with signals from the sensor(s) connected to the housing of the data logger being usable as inputs to feedback or feedforward control processes which may be selected, by a user of the data logger, from a wide range of options in engineering and scientific applications.

In a further aspect, the present invention provides a data logger system or a process control system comprising:
at least one sensor;
at least one data logger as described above communicating with a process control unit, said data logger comprising
a sensor interface for connecting at least one sensor to a housing of the data logger;
an accessible memory for storing data received from said at least one sensor; and
a controller for controlling operation of the data logger; and
at least one actuator controllable by the process control unit in response to signals received from said at least one sensor and logged by the data

Conveniently, the process control unit interfaces with a selected at least one sensor sensing an input for control. If a selected sensor input triggers a control response, the process control unit may be conveniently programmed to manage the control response or continue sampling—at a desired time interval—from another sensor and not to sample data from the selected sensor until the microprocessor flags that the control response is complete. This enables more efficient utilisation of computing resources.

The sampling rate of the sensor input may be set by a user, conveniently through at least one of a web user interface, a mobile app and a script placed on accessible memory. The sampling rate may advantageously be greater than an available wireless communications network speed. In this regard, sampling rate of a conventional data logger over a network would be typically once per second or less, whereas sensors forming part of a data logging system as described here may be polled at significantly higher rates, for example many hundreds of times per second which cannot typically be sent over a network. The data logger system of the present invention allows signal processing on board the data logger with communications over a wireless network either not being provided or being optional during logging.

The data logger conveniently accepts mixed sensor inputs. The process control unit may direct digital and/or analogue signals to LAM(s)

In embodiments, a data logger or process control system may comprise a server communicable with a data logger, as described above, and the server may enable a user to configure said data logger. A user may configure a data logger directly via the server.

Such a server may communicate with a memory for storing data, data from said data logger being stored in said memory. Conveniently, the server is communicable with a user network for download of software and firmware to operate said data logger and a user may configure said data logger via the user network, conveniently through a user device

The server or the user network is communicable with cloud based memory for storage of data from said data logger.

The data logger is readily configurable for edge computing as described for embodiments below.

The data logger as well as data logging or process control systems utilising it is conveniently robust to cater for a wide range of engineering and scientific applications where environmental factors present a real risk of damage. Factors that may be significant include water and/or dust ingress and damage. To reduce such risks, the modular sensor interface includes a sealing arrangement to reduce or eliminate risk of water or dust passing through a gap between the housing of the data logger and a sensor or sensor cable.

The data logger is conveniently connectable with a range of sensors which could include-without limitation-temperature sensors, moisture sensors, relative humidity sensors, gas composition sensors, optical sensors, acoustic sensors, motion sensors, pressure sensors, current sensors, voltage sensors, position sensors, other environmental parameter sensors and so on. Desirably, the data logger is connected to a plurality of sensors sensing different parameters such that the data logger accepts mixed inputs. The data logger is also conveniently connectable with actuators including flow control valves, switches, stepper motors and actuators whether ON/OFF, ON with direction or using pulse width modulation. The data logger may conveniently be used in combination with a control system, such as a SCADA control system, with analogue and/or digital inputs from the control system being directed to LAM(s) as described above and vice versa.

The data logger conveniently includes on-board sensors, such as those described above, and which may include an accelerometer to sense motion and/or a position sensor such as a GPS or satellite based navigation sensor (for example a GLONASS sensor), which may allow positioning to within a small distance, even a few centimetres (using onboard RTK GPS chipsets) The data logger—conveniently the CCM—may include an air vent for sensors, such as barometric sensors and air quality index sensors, requiring this.

Data loggers and data logger or process control systems as described above are flexible, suitable for use by hobbyists and professionals including scientists and engineers, and allow user configuration to a broader extent than previously and have a relatively low price.

### BRIEF DESCRIPTION OF THE DRAWINGS

Further features of the present invention are more fully described in the following description of several non-limiting embodiments thereof. This description is included solely for the purposes of exemplifying the present invention. It should not be understood as a restriction on the broad summary, disclosure or description of the invention as set out above. The description will be made with reference to the accompanying drawings in which:

FIG. 1 is an orthogonal view of a data logger according to one embodiment of the present invention.

FIG. 2 is a schematic orthogonal view of a logging and/or actuation module (LAM) of data logger of FIG. 1 during assembly.

FIG. 3 is a schematic partial orthogonal detail section view of the data logger as schematically shown in FIG. 2 and showing connection of terminal blocks to the circuit board of the LAM.

FIG. 4 is a further schematic partial orthogonal detail section view of the LAM of the data logger shown in FIG. 3.

FIG. 5 is a schematic orthogonal view of the sealing arrangement between the data logger of FIGS. 1 to 4 and a base plate.

FIG. 6(a) is an orthogonal section view of a sealing plug to close a sensor or actuator port as shown in FIGS. 1 and 2.

FIG. 6(b) is an orthogonal section view of one embodiment of a sealing clamp element to seal a sensor cable to a data logger as shown in FIGS. 1, 3 and 4.

FIG. 6(c) is an orthogonal section view of a further embodiment of sealing clamp element to the sealing clamp shown in FIG. 6(b).

FIG. 7(a) is an orthogonal view of a further sealing clamp element to be used in conjunction with the sealing clamp element shown in FIGS. 6(b) and 6(c).

FIG. 7(b) is a side view of the further sealing clamp element shown in FIG. 7(a).

FIG. 7(c) is a front view of the further sealing clamp shown in FIGS. 7(a) and 7(b).

FIG. 8 is a schematic orthogonal view of the data logger of FIG. 2 with a power cable and sensor cable clamped to the data logger.

FIG. 9 is an orthogonal detail section view showing the clamping of a sensor cable to the data logger of FIG. 8 using the further sealing clamp of FIGS. 7(a) to 7(c).

FIG. 10 is a side detail section view showing the clamping of a sensor cable to the data logger of FIG. 8 using a combination of the sealing clamp elements of FIGS. 6(b) and (c) and FIGS. 7(a) to 7(c).

FIG. 11 is a schematic orthogonal view of the data logger of FIG. 8 with a retainer plates connected over the sensor ports and power and communications ports.

FIG. 12(a) is a front orthogonal view of a connector used to connect the LAM of the data logger as shown in FIG. 8 to the control and communications module (CCM) or another LAM of the data logger.

FIG. 12(b) is a side view of the connector shown in FIG. 12(a).

FIG. 12(c) is a side section view of the connector shown in FIGS. 12(a) and 12(b).

FIG. 13(a) is an orthogonal view of a retainer comb for use in the connection of the LAM and CCM of the data logger shown in FIG. 8.

FIG. 13(b) is a top view of the retainer comb shown in FIG. 13(a).

FIG. 14 is a top orthogonal view of the LAM of FIG. 8 showing the connectors and retainer combs of FIGS. 12 and 13 in position ready for connection of a further LAM or the control and communications module (CCM).

FIG. 15 is a top orthogonal view of the data logger of FIG. 14 with a CCM secured in position.

FIG. 16(a) is a partial section view of the data logger of FIG. 15 showing mechanical connections between one embodiment of CCM and LAM.

FIG. 16(b) is a partial section view of the data logger of FIG. 15 showing mechanical connections between a further embodiment of CCM and LAM.

FIG. 17(a) is a further section view of the data logger of FIGS. 15 and 16(a).

FIG. 17(b) is a further section view of the data logger of FIGS. 15 and 16(b).

FIG. 18 is a detail side view showing connection of the LAM and CCM of the data logger of FIGS. 14 to 17.

FIG. 19(a) is an orthogonal view of a protective shield used during assembly of the data logger of FIGS. 15 and 16.

FIG. 19(b) is a top orthogonal view showing a portion of a first alternative embodiment of protective shield to that shown in FIG. 19(a).

FIG. 19(c) is a top orthogonal view showing a portion of the protective shield to that shown in FIGS. 19(a) and 19(b).

FIG. 20 is a detail top orthogonal view showing a power and communications connector block for the data logger of FIGS. 14 to 18.

FIGS. 21(a) to (c) are views showing electrical and communications connections between the LAM and first embodiment of CCM (or LAM and further LAM) of FIGS. 15 and 16.

FIGS. 21(d) and (e) are partial orthogonal views showing how electrical and communications connections are made between the LAM of FIGS. 16(b) and 17(b) and a second embodiment of CCM.

FIG. 21(f) is a side section view showing connection between the LAM of FIGS. 16(b) and 17(b) and the second embodiment of CCM.

FIG. 22 is a partial front orthogonal detail view of the LAM of FIGS. 15 and 16 with sealing flap for USB and SD card ports closed.

FIG. 23 is a partial front orthogonal detail view of the LAM of FIGS. 15 and 16 with sealing flap for USB and SD card ports removed.

FIG. 24 is a partial top orthogonal section view with hidden detail showing the front circuit board and indicators of the LAM of FIGS. 15, 16, 22 and 23.

FIG. 25 is a top orthogonal view showing the front circuit board of FIG. 24 connected to a wall of the LAM.

FIG. 26 is a top orthogonal view showing a portion of the protective shield of FIG. 19 in position over the front circuit board as shown in FIG. 25.

FIG. 27 is a front orthogonal partial section view with hidden detail showing detail of the front wall of the LAM of the data logger shown in FIGS. 15 and 16.

FIG. 28 is an orthogonal detail view of part of the front wall of the LAM of the data logger shown in FIGS. 15, 16 and 28 and showing button and holes for directing light from the LAM indicators.

FIG. 29 is an orthogonal view of part of the front wall showing part of a sealing element and diffuser for the LAM indicators in position within a hole for directing light from a LAM indicator.

FIG. 30 is a top orthogonal view showing detail of part of the front wall as shown in FIG. 29 in relation to other components of the LAM.

FIG. 31 is an orthogonal view showing the data logger of FIG. 1 fitted with a mounting bracket for fitting to a mounting point, such as a DIN rail, according to one embodiment of the present invention.

FIG. 32 is a schematic orthogonal view showing the data logger and fitted mounting of FIG. 31 fitted to a beam mounting point in the form of a DIN rail.

FIG. 33 is a front orthogonal view of the sealing and diffuser element of FIG. 28.

FIG. 34 is a rear orthogonal view of the sealing and diffuser element shown in FIG. 33.

FIG. 35 is a schematic top orthogonal view showing the arrangement of the front circuit board and sealing and diffuser element of FIGS. 33 and 34.

FIG. 36 is a top orthogonal view of the additional circuit board for the CCM including the sealing and diffuser element and button.

FIG. 37 is a top orthogonal view of a data logger according to a second embodiment of the present invention.

FIG. 38 is a front orthogonal view of the data logger of FIG. 37.

FIG. 39 is a partial section view of the data logger of FIGS. 37 and 38.

FIG. 40 is a first partial top orthogonal view showing the interior of the LAM of FIGS. 37 to 39.

FIG. 41 is a first schematic top orthogonal view showing the interior of the LAM of FIGS. 37 to 40.

FIG. 42 is a first partial top orthogonal view showing the interior of the LAM of FIGS. 37 to 41.

FIG. 43 is a second schematic top orthogonal view showing the interior of the LAM of FIGS. 37 to 42.

FIG. 44 is a partial schematic top view showing detail of the connection between the front circuit board and the main circuit board of the LAM of FIGS. 37 to 43.

FIG. 45 is a first partial top orthogonal view showing the relationship between terminal block and stacking connector portion of the protective shield of FIG. 19(b).

FIG. 46 is a partial top orthogonal view showing connection between the stacking connector, the flexible circuit board and the main circuit board of the data logger of FIGS. 37 to 39.

FIG. 47 is a top orthogonal view of a connector plate of FIG. 46.

FIG. 48 is a bottom orthogonal view of the connector plate of FIGS. 46 and 47.

FIG. 49 is a second partial top orthogonal view showing the relationship between terminal block and stacking connector portion of the protective shield of FIG. 19(b).

FIG. 50 is a partial orthogonal section view showing the relationship between the protective shield, retaining plate and circuit boards of the LAM of FIGS. 37 to 43.

FIG. 51 is a partial top orthogonal view showing the interior of the LAM of FIGS. 37 to 43 and showing terminal blocks and the front wall.

FIGS. 52(a) and 52(b) are orthogonal views of the front circuit board of the LAM of FIGS. 37 to 43.

FIG. 53 is a partial side view of the LAM of FIGS. 37 to 43 showing electrical connection for all functions on the front circuit board of the LAM and the main circuit board.

FIG. 54 is a top orthogonal section view of the front wall of the LAM of FIGS. 37 to 43 showing the diffuser and front flap for SD card and USB ports.

FIG. 55 is a partial front orthogonal view of the front wall showing the ports for SD card and USB connector together with the button for the LAM.

FIG. 56 is a partial side section view showing a portion of the front flap and connection with the USB connector port.

FIG. 57 is a front top orthogonal view of the front flap for the SD card and USB ports.

FIG. 58 is a rear top orthogonal view of the front flap for the SD card and USB ports.

FIG. 59 is a partial top orthogonal view of the front wall showing a portion of the front flap and connection with the USB connector port.

FIG. 60 is a partial orthogonal view showing the relationship between the front flap and a reset button for the data logger of FIGS. 37 and 38.

FIG. 61 is a partial side section view showing the relationship between the front flap and a reset button for the data logger of FIGS. 37 and 38.

FIG. 62 is a top perspective view of a partly assembled CCM according to a second embodiment of the present invention.

FIG. 63 is a schematic side view of a CCM according to the second embodiment of the present invention.

FIG. 64 is a partial schematic top orthogonal view of the CCM of FIG. 61 showing the port for a sensor requiring air ingress.

FIG. 65 is a detail side section view of the CCM of FIG. 63 showing the port for a sensor requiring air ingress.

FIG. 66 is a top orthogonal view of a part assembled data logger according to the second embodiment and schematically showing the main CCM circuit board and communications modules.

FIG. 67 is a first top orthogonal view of the part assembled data logger of FIG. 66 and showing the circuit board of FIG. 66 and an auxiliary circuit board for the CCM of FIG. 63.

FIG. 68 is a second top orthogonal view of the part assembled data logger of FIG. 66 and showing the circuit board of FIG. 66 and an auxiliary circuit board for the CCM of FIG. 63.

FIG. 69 is a top orthogonal view of a partially assembled CCM with a top mounted antenna according to a third embodiment of the present invention.

FIG. 70 is a top orthogonal view of a partially assembled CCM with three top mounted antennae according to a fourth embodiment of the present invention.

FIG. 71 is an orthogonal view of a data logger with four top mounted antennae according to a fifth embodiment of the present invention and prior to connection of power, sensor and actuator cables.

FIG. 72 is an orthogonal view of a data logger with four top mounted antennae according to a sixth embodiment of the present invention and following connection of power, sensor and actuator cables.

FIG. 73 is a top orthogonal view of a LAM for a battery-operated data logger according to a seventh embodiment of the present invention.

FIG. 74 is a top orthogonal view of the LAM of FIG. 73 with the protective shield of FIG. 19(c) in position.

FIG. 75 is a side view showing a data logger comprising a stack of LAMs connected to a CCM according to an eighth embodiment of the present invention.

FIG. 76 is a partial side section view of the data logger of FIG. 75 showing mechanical connections between the LAMs and CCM.

FIG. 77 is a partial side section view of the data logger of FIGS. 75 and 76 showing electrical connections between the LAMs and CCM.

FIG. 78 is a partial side section view of a data logger with similar external appearance to FIGS. 75 to 77 according to a further embodiment of the present invention.

FIG. 79 is a side orthogonal view showing electrical and communications connections between the LAM and CCM circuit boards in the data logger of FIG. 78.

FIG. 80 is a top orthogonal view of the LAM circuit board of FIG. 79.

FIG. 81 is a bottom orthogonal view of the LAM circuit board of FIGS. 78 and 79.

FIG. 82 is an orthogonal view of a connector used to make electrical and communications connections between the LAM and CCM circuit boards in FIG. 79.

FIG. 83 is a top orthogonal view of the bottom LAM in the data logger of FIG. 78.

FIG. 84 is a detail view of the bottom LAM of FIG. 83 showing relationship between a vertical circuit board and the protective shield.

FIG. 85 is a block diagram showing a data logger system of a first embodiment of the present invention.

FIG. 86 is a block diagram showing a data logger system variant of the data logger system of FIG. 85.

FIG. 87 is a block diagram of a data logger system of a second embodiment of the present invention.

FIG. 88 is a block diagram of a data logger system variant of the data logger system of FIG. 87.

FIG. 89 is a block diagram of a data logger system of a third embodiment of the present invention.

FIG. 90 is a block diagram of a water reticulation control system using data loggers of embodiments of the present invention.

FIG. 91 is a schematic flow diagram showing the logic for operating the water reticulation control system of FIG. 90.

FIG. 92 is a block diagram of an electric vehicle control system using data loggers of embodiments of the present invention.

FIG. 93 is a schematic flow diagram showing the logic for operating the electric vehicle control system of FIG. 92.

FIG. 94 is a schematic of the electronic and communications architecture for a data logger as shown in FIGS. 78 and 79.

FIG. 95 shows a range of exemplary widgets that may be used in systems such as those shown in FIGS. 90 and 91.

### DESCRIPTION OF PREFERRED EMBODIMENTS

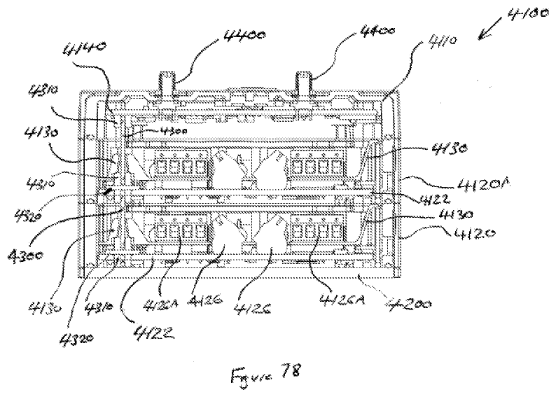

Referring to FIG. 1, a data logger 100 comprises at least two modules:
a logging and/or actuation stacking module (LAM) 120; and
a control and communications module (CCM) 110
   which are here integrated within a single box 100 to form the data logger, as shown here for purposes of example. A data logger system comprising the CCM 110 and LAM(s) 120 will vary with the complexity of the system, in terms of the sensors and actuators to be included. The system and its sensor and actuator components are selected and configurable by a user, for example using additional LAM(s) 120. However, in preferred embodiments, a single CCM 110 is provided whilst a plurality of LAMs 120 may be provided in a stack as shown in FIGS. 75 to 77. In this first embodiment, for purposes of illustration, the LAM 120 and CCM 110 are integrated into one box or block 100.

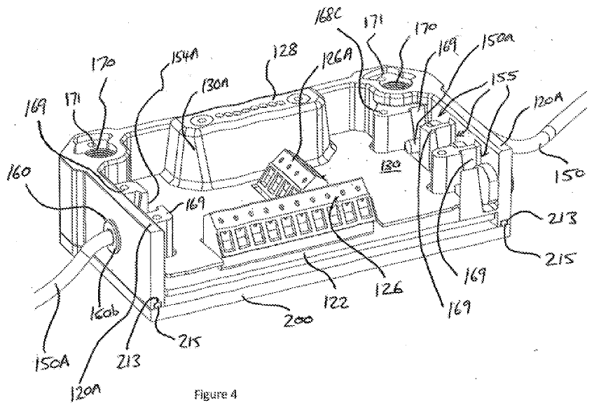

Data logger block 100 comprises a top portion as CCM 110 and a bottom portion as LAM 120. This split of the data logger block 100, and the ability to remove the top portion 110 allows the user to easily mount and then work on the data logger block 100 from the top only, without affecting any cables 150 wired into the LAM 120 of data logger block 100. For purposes of illustration, one sensor or actuator cable 150 and one power cable 150A is shown in each of FIGS. 1, 2 and 4 and elsewhere in the drawings. Such an arrangement would be suitable for a simple data monitoring application where sensor signals are simply acquired for processing.

The LAM 120, and any additional LAMs (not shown) to which the user's data logging system may require it to be connected, may be electrically connected, as described below, is here made from diecast and painted aluminium and is robust, in terms of resistance to vibration and impact, for a range of applications. Other suitable materials for fabrication of LAM 120 could be used as known in the art.

LAM 120, and so data logger 100, is secured into place by screwing it down, using a 100×100 mm square array of M4 holes 210, fitted with screws 182, to a base plate 200. A range of base plate designs could be used. LAM 120 may also be connected, by screws or other suitable fasteners, to any flat surface provided with, where screws are used, the threaded holes available to mount against. At the bottom edge of the LAM 120 is a rubber O-ring 215 fitted into a groove 213. As schematically illustrated by FIG. 5, rubber O-ring 215 extends around the bottom edge of the LAM 120 of data logger block 100 sealing it, in a manner effective to prevent water and dust ingress, to the base plate 200. Desirably, the rubber O-ring 215 does not volume lock and should allow a hard stop between the housing of LAM 120 and base plate 200.

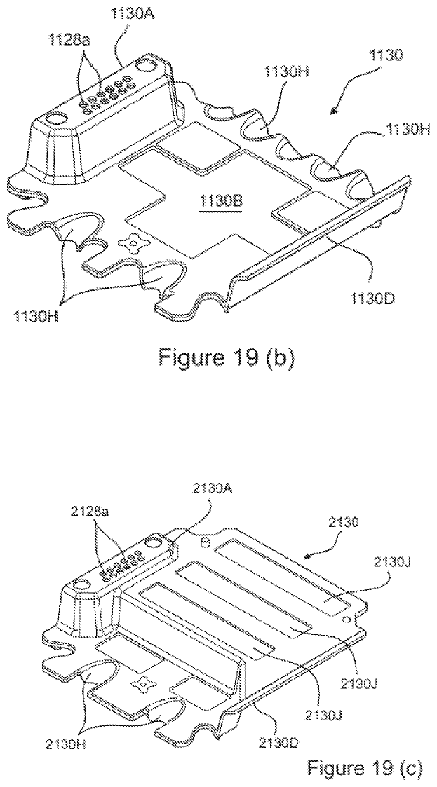

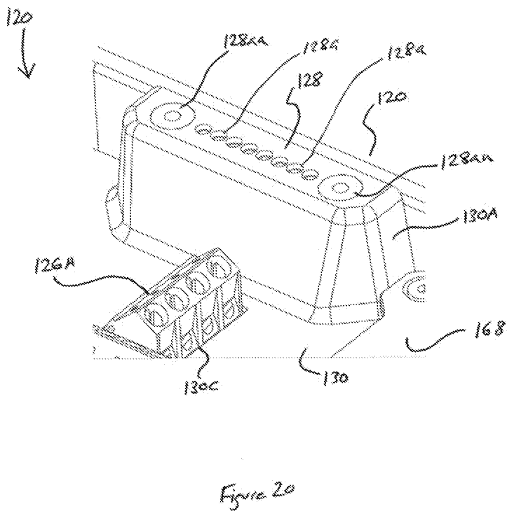

After screwing the LAM 120 into base plate 200, the user can then wire up their desired data logger system—which will vary with each data logging application and consequently in complexity from simple to complex—with the top of the LAM 120 open, and without CCM 110 in place. The wiring up step involves threading of wires, such as sensor and actuator cables 150, through the cable sealing and clamping arrangements as described below. During wiring up, the circuit board 122 of LAM 120 is protected by protective shield 130 as described further below with reference to FIG. 19.

In the embodiment shown, two cable sealing and clamping ports 154A, 154B, are provided on the left hand side of the LAM 120 of data logger block 100, and five ports 155 are provided on the right hand side of the LAM 120. The port arrangement may be different in other embodiments, for example a different number of ports may be selected.

The left-hand side ports 154A, 154B are designated for power and CAN communications (RS485 communications could be used in an alternative embodiment) which are conveniently provided by a four-wire cable (power (PWR), ground (GND) with a twisted pair for the CAN communications) under the control of a microcontroller of the CCM 110. The cable 150A extending through port 154A terminates into one of the 4 pin terminal blocks 126A mounted on the main circuit board 122 inside the data logger block 100. The second left hand side port 154B can be used to ‘daisy chain’ the power supply and CAN bus to another data logger block (not shown) to extend the user's data logger system, if required. Such other data logger block may be of the form presently described though ‘daisy chaining’ to other devices or data logger types is not precluded. In the embodiment shown, this ‘daisy chaining’ is not required and so the port 154B is closed with a sealing plug 162, as further described below.

Data logger 100 includes electrical safety circuits to ensure safe connection to power, communications, sensors and actuators and to avoid short circuits caused by accidental misuse.

In this embodiment, five ports 155 are provided on the right-hand side of the LAM 120 of data logger block 100. A greater or smaller number of ports can be provided. The provision of five ports 155 allows accommodation for up to five cables to be connected to the data logger block 100 while being fully sealed at the ports 155, as described below. It is to be understood that, in other embodiments, such full sealing may not be required.

Ports 155 are intended to be used, at the convenience of the user, to interface with a range of sensors (for example moisture or temperature sensors) and/or actuators (for example flow control valves or stepper motors or other actuator (whether ON/OFF, ON with direction or with pulse width modulation (PWM)) as required, for example, by the user's process control system. The ports 155 allow interface of cables extending through them, when required, with a desired number of terminal blocks and pins (e.g. 2×10 pin terminal blocks 126) (subject to space constraints) fitted to circuit board 122 to provide power and signals to and from the sensors or actuators and on to any microprocessor or microcontroller used for process control which may include microcontroller(s) on board the data logger block 100 with one microcontroller being provided for CCM 110 and each LAM 120. A microprocessor may be employed for some applications. Allocation of the particular pins may be factory set, as required and different pin allocation may be offered depending on application.

After the cables 150, 150A—in the embodiment shown—have been physically positioned in, and electrically terminated in respective terminal blocks 126, 126A of the LAM 120; the cables 150, 150A are sealingly clamped to the LAM 120 and the data logger block 100 using a combination of sealing clamp elements 160, 165.

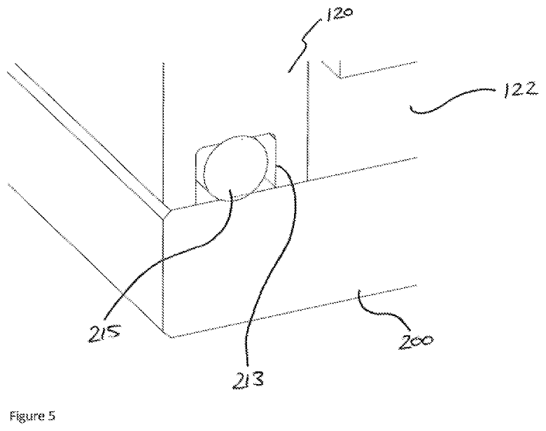

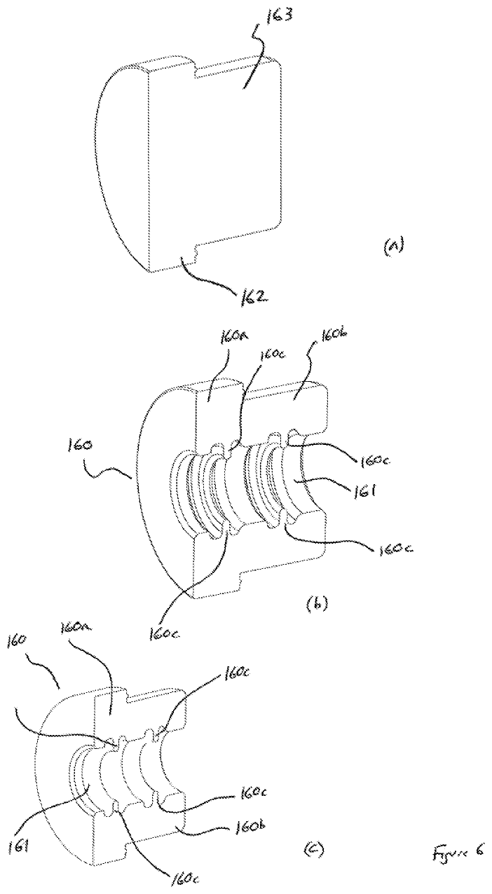

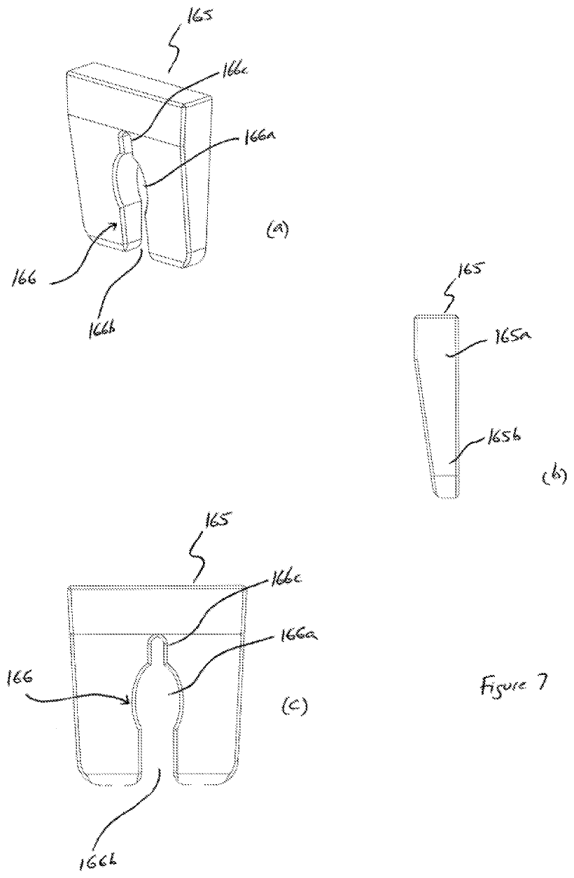

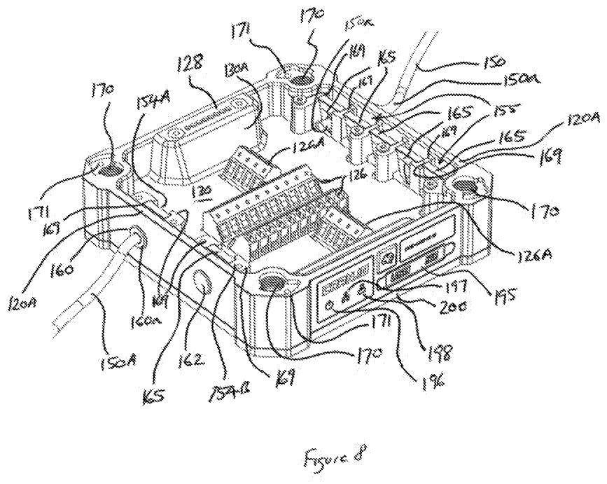

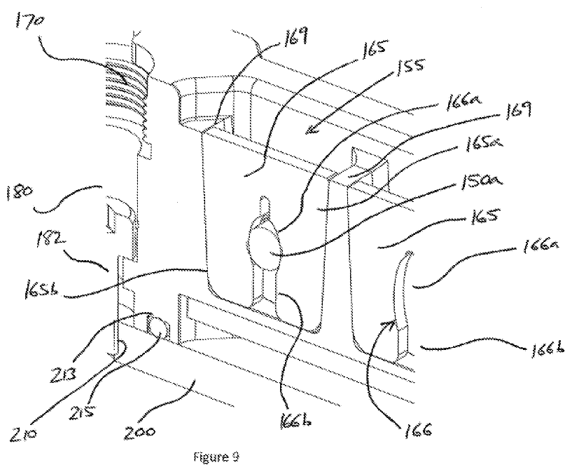

Referring now to FIGS. 6(b) and (c) and 7(a) to (c), there are shown sealing clamps comprising complementary sealing clamp elements 160, 165, that allow connection of cables 150, 150A to LAM 120 of data logger block 100, while preventing dust or water ingress into the data logger block 100, in some embodiments such as for field applications, for example in process plants. The sealing clamps 160, 165 allow achievement of at least an IP67 rating and desirably an IP68 ingress rating according to IEC Standard 60529, the contents of which are hereby incorporated herein by reference, to be achieved. As shown, the cable seal clamp elements include a tubular sleeve 160 and a wedge 165.

Sleeve 160 has a cylindrical head 160a which, in use, sits against an inside wall 120A of the data logger housing (here the outer wall of LAM 120 but the same principle applies whether the sleeve 160 is used in the clamping and sealing of a cable in the CCM 110 or LAM 120), a smaller diameter tube portion 160b for extending through the bore 155a of the port; and bore 161 for accommodating the end 150a of sensor or actuator cable 150. The bore 161 of each sleeve 160 is configured to provide a double lip seal of sleeve 160 to cable 150, and more particularly cable end 150a, through engagement of lips 160c with cable end 150a. The sleeve 160 provides a tolerance for cable end 150a diameter. For example, the bore 161 of sleeve 160 may conveniently accommodate a 1 mm nominal difference in cable diameter per different size of seal between 2 mm and 7 mm diameter cables. A blanking sealing element 162 is provided if any port 154A, 154B, 155 is not to be used.

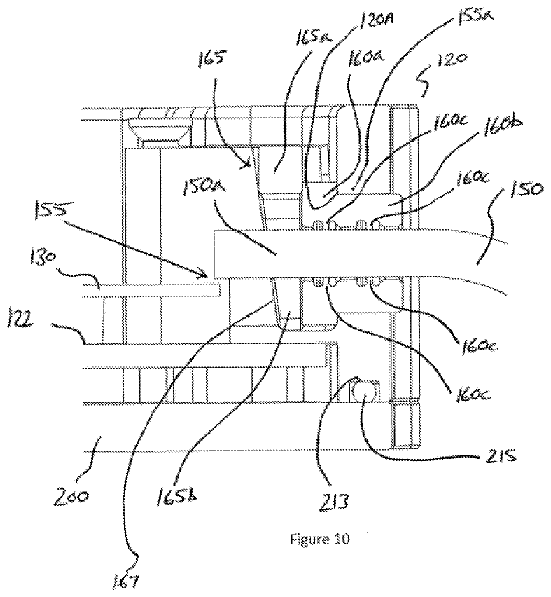

A wedge 165 is provided for each sleeve 160 to complete the seal arrangement as shown in FIGS. 8 to 10. The wedge 165 is pressed down through slots formed in the side walls 169 of port 155 over the cable end 150a into the angled wedge cavity 167. Side walls 169 act as guides for wedge 165 and also for location of the tubular sleeve 166 and associated cable end 150a. Pressing down creates a pinching effect on the cable 150 as well as forcing the seal up against the inside face of the outer wall 120A of the LAM 120 of the data logger block 100 ensuring complete cable sealing at that inside face of outer wall 120A. The angled back face of wedge 165 is configured to enable such sealing. The pinching effect is achieved through provision of a slot 166 formed in wedge 165, the slot having narrow sections 166b and 166c and a wider section 166a smaller than the cable end 150a diameter. The narrow section 166b is formed in a thinner section 165b of wedge 165 so can flex to admit the cable end 150a into the wider section 166a. As the wedge 165 is pressed down further into the wedge cavity 167, the cable is pinched by wider section 166a so creating the pinching effect that completes clamping of the cable end 150a at port 155. Narrow section 166c, providing less stiffness to the wedge 166, gives mechanical relief to the major pawls to bend inward so that wider section 166a pinches the cable.

As to sealing of the cable end 150a to LAM 110, this involves action of wedge 165. Specifically, as wedge 165, with its angled back face, is pushed into position within angled slot 167 in wall 169 (extending toward outer wall 120A of LAM 120), the wedge 165 is pushed laterally outboard towards wall 120A of LAM 120. This forces an annular surface of portion 160a into sealing contact with wall 120A. This sealing of cable end 150a to LAM wall 120A at a port 154A, B154, 155, as described above, allows—with the sealing O-ring 213 described above—the IP68 rating to be met by data logger block 100. Sealing of cable end 150a involves sealing of ingress along the cable 150 path and sealing of ingress through the outside of the seal and LAM wall 120A.

It will be understood that, in the embodiments shown, each cable 150, 150A connected to the data logger 100 would be sealingly clamped into position as described above. Each port 155 is configured in the same way as described above to enable such sealing clamping to occur. Further, the end of cable 150A is sealingly clamped into position at port 154B in the same manner as described above. When clamped into position, cable ends 150a cannot practically be pulled out, for example due to someone tripping over a cable 150, and potentially disconnecting the electric terminal blocks 126, 126A from the circuit board 122 which could be an electrical risk. The clamping and sealing elements as described above do this while avoiding the need for expensive cable connectors. However, in other embodiments, sealing may not be required (for example where the data logger is used indoors in a workshop or laboratory type environment). Standard cable connectors could be used instead.

If ports 154B, 155 are not in use, they can be plugged through sealing plugs 162 as shown in FIG. 6(a). In this case, wedging with wedges 165 prevents the sealing plugs 162 falling inward. A lubricant may be required during assembly of the sealing clamps to avoid excessive deformation of the tubular sleeves 160 in the wrong direction, i.;e vertically when the wedge 165 is forced downward, rather providing a lateral force on the tubular sleeve 160 to form an effective seal.

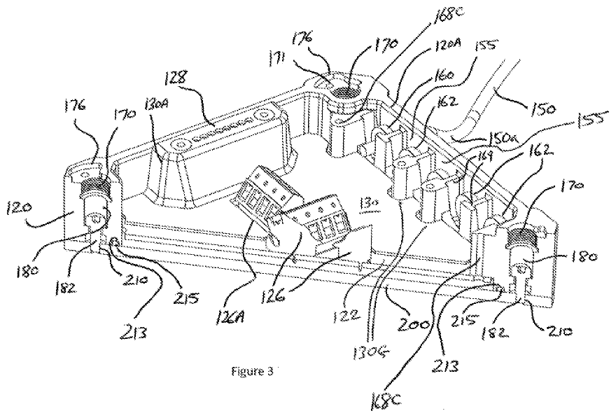

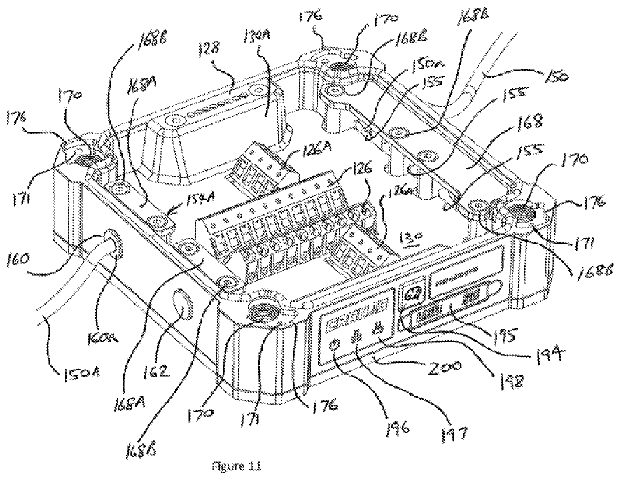

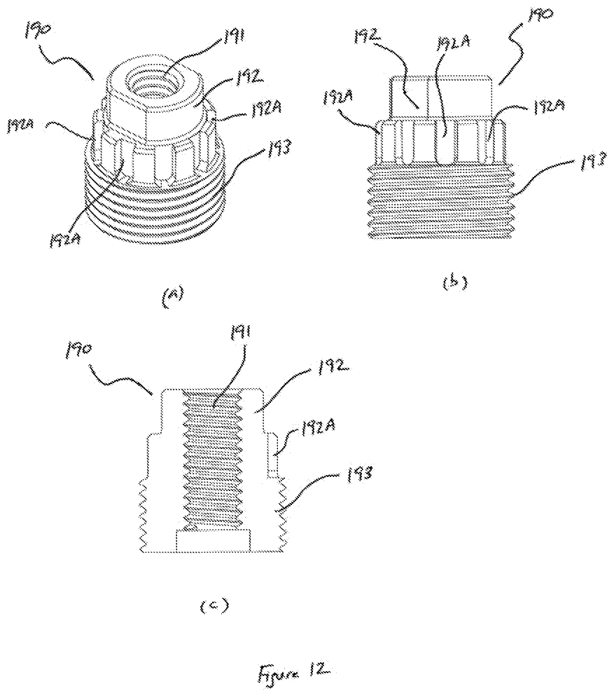

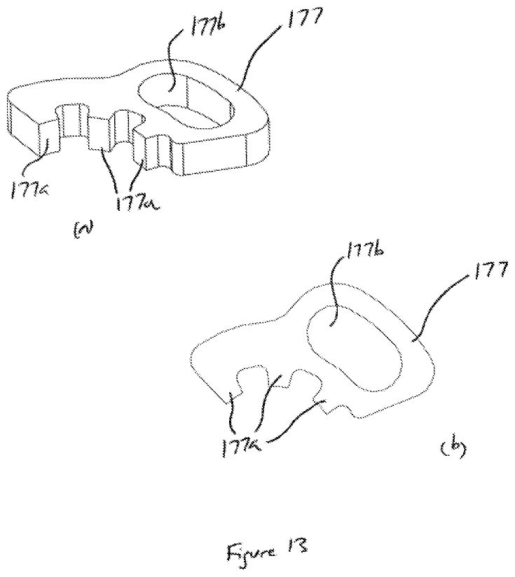

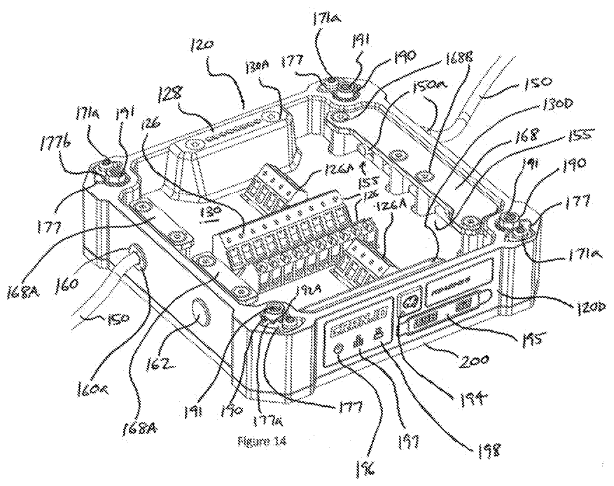

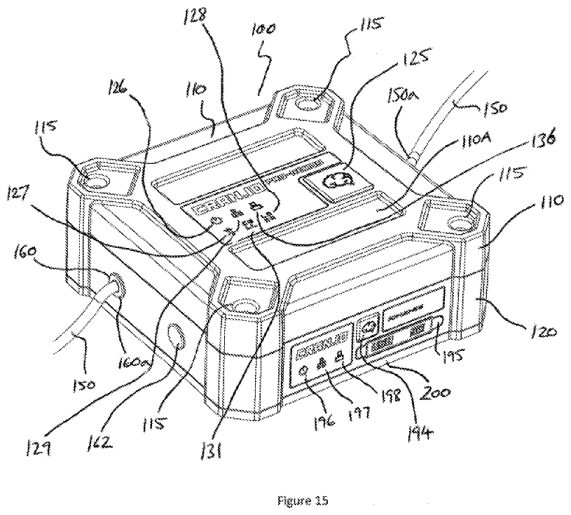

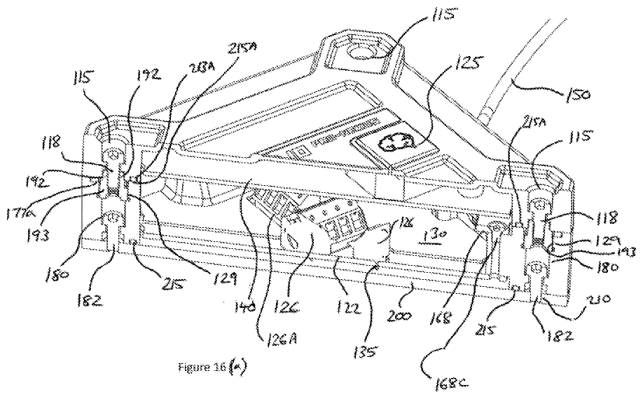

The wedges 165 are forced downward to secure, through a clamping seal, the cables 150, 150A by screwing the retainer plates 168, 168A to the walls 169 of the bottom portion 120 using associated screws 168B as shown in FIG. 14. For retainer plate 168, screws 168B bolt into threaded bores 168C as shown in FIGS. 3, 4, 16 and 17.

In another embodiment, CCM 110 could involve the above-described sealing and clamping elements to accommodate power and CAN communications to CCM 110 directly. However, in such embodiment, the sealing clamp elements would be assembled from the underside of CCM 110, being turned around 180 deg, clamping upward in the CCM. Such a CCM 110 could be secured directly to the bottom mounting plate 200 rather than to a LAM 120.

It is convenient to work on LAM components from above. To assist in the illustrated embodiment, a plastic protective shield 130, as shown in detail in FIG. 19(a), is provided above the main circuit board 122 to shield the electronic components from being touched by the user while assembling the data logger 100, as well as the cables rubbing on the electronics during operation. Protective shield 130 is provided with raised portion 130A for covering power connection block 128, slots 130B, 130C and 130E for respectively accommodating terminal blocks 126 and 126A, raised portion 130D for protecting the front circuit board 191 and associated componentry as described below, and slots 130G for accommodating walls 169 defining ports 155.

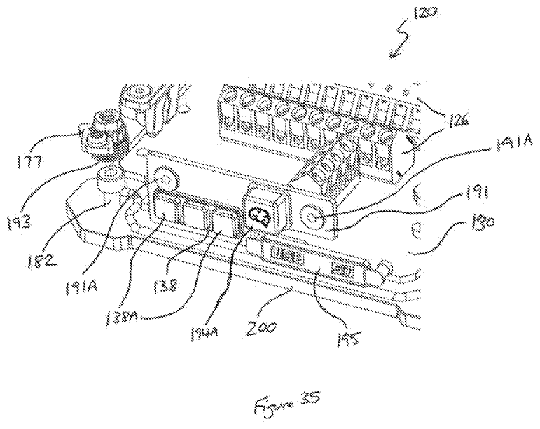

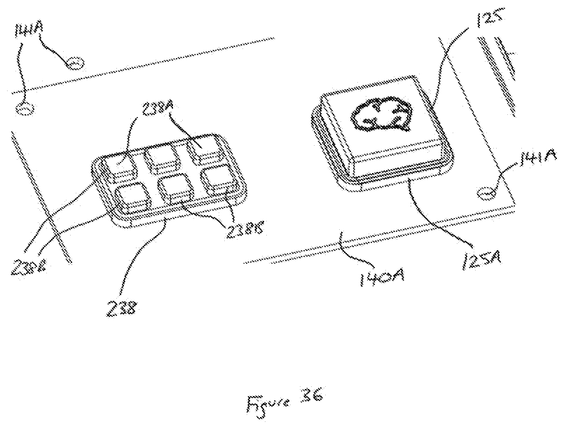

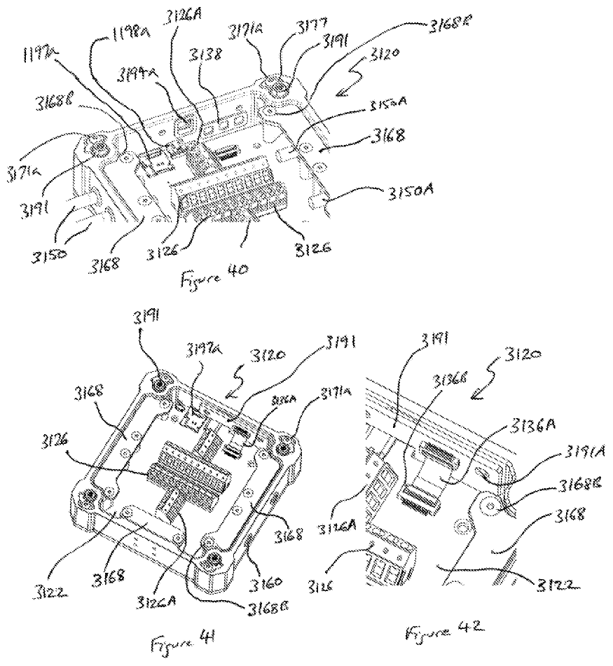

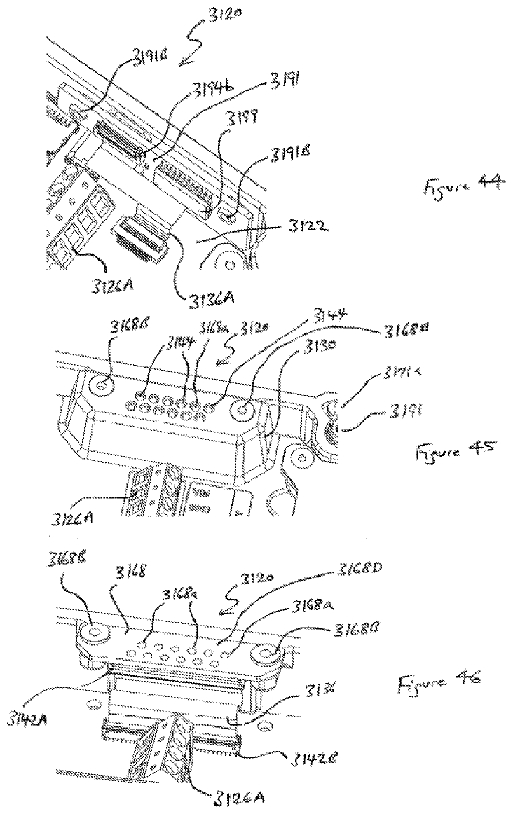

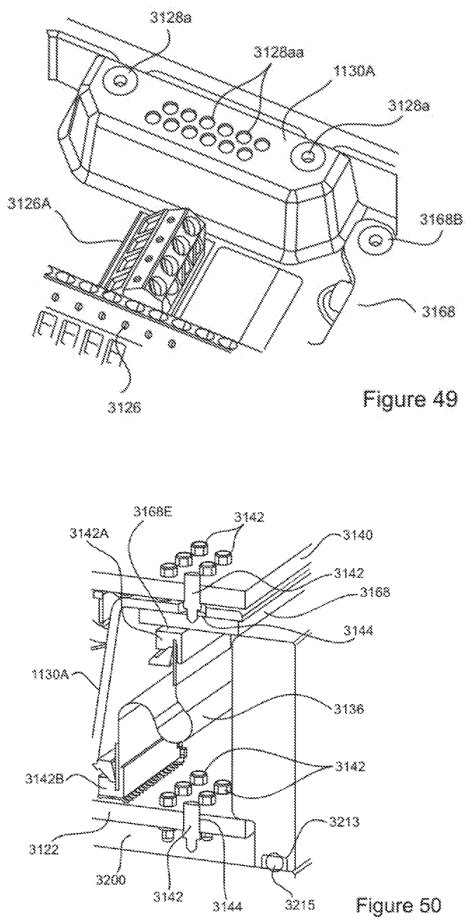

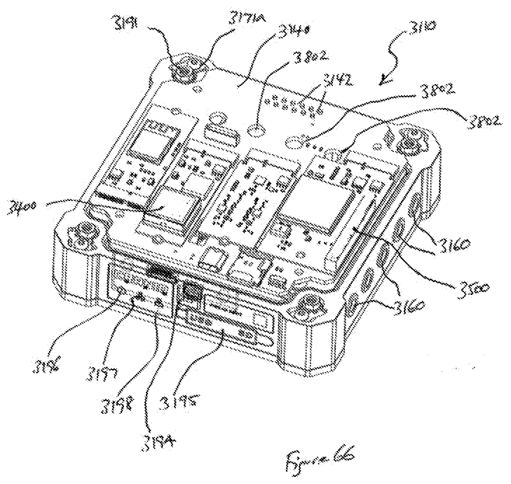

Alternative forms of plastic protective shield 1130 and 2130 are shown in FIGS. 19(b) and 19(c) with slots 1130A-G and 2130A-G varying dependent upon the data logger components to be accommodated, whether standard cable connectors are to be included and whether the data logger is battery powered as described further below. FIG. 19(b) shows a protective shield 1130 suitable for a data logger similar to that already described (and for which reference numbers are, unless otherwise provided, common but for the prefix “3”) but in which standard cable connectors are used. Slot 1130B accommodates terminal blocks 3126 and 3126A of the data logger further described below with reference to FIGS. 37 to 72. Slots 1130H are in a scallop shape with an inwardly curved slope which assists connection of standard cable connectors.

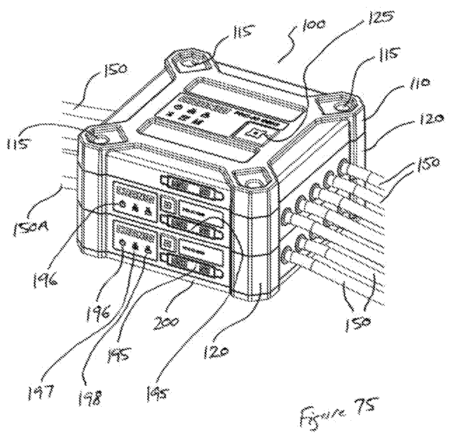

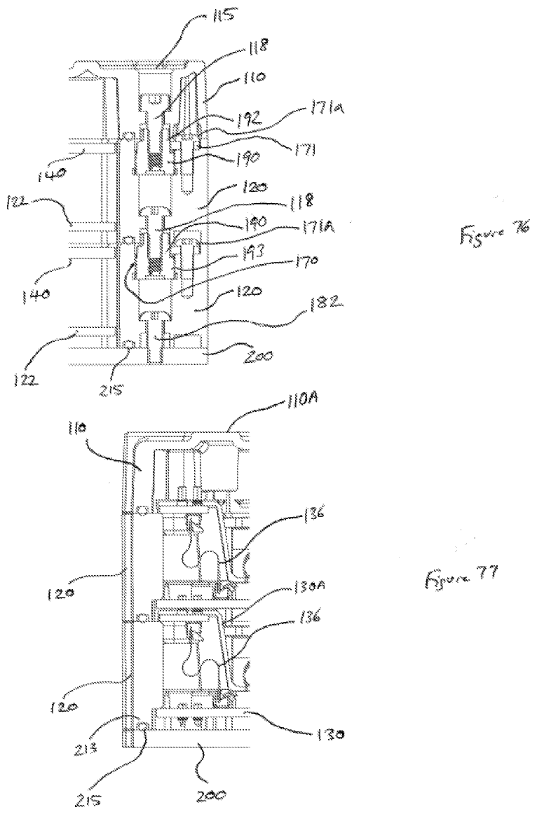

FIG. 19(c) shows a protective shield 2130 suitable for a data logger, which other than being battery powered, is similar to that already described (and for which reference numbers are, unless otherwise provided, common but for the prefix “2”) but in which standard cable connectors are used. The three slots 2130J accommodate the three batteries 2500 of a data logger for which the LAM 2120 is shown in FIGS. 73 and 74.

The LAM 120 of the data logger block 100 is then made ready for either another logging and actuation module or block or, alternatively as shown here, the control and communication module (CCM) 110 to be positioned and secured into place. In either case, as shown by FIG. 14, this step is achieved by installing the connectors 190 and retaining combs 177 within wells 170 and comb retainers 176 provided at each corner of the LAM 120. Screws are convenient fasteners for this purpose and, for example, M2.5 panhead screws 171 can be used. Such installation is readily done by the user working from above the LAM 120. Screw 118 is, for example, a M4 cap head hex screw and conveniently screws 118 and 182, for securing LAM 120 to base plate 200, are the same.

Connector 190 is shown in FIG. 12 and retaining comb 177 is shown in FIG. 13. Connector 190 is a tubular component with an upper portion 192 and lower threaded portion 193 with a bore 191 extending through it. Retaining comb 177 has tines 177a to securely grip the connector 190, fitting within splines 192A of connector 190, when fastened into position as described below. Aperture 177b accommodates a screw 171a for securing retaining comb 177 into its retainer 176 through bores 171 as shown, for example, in FIG. 8.

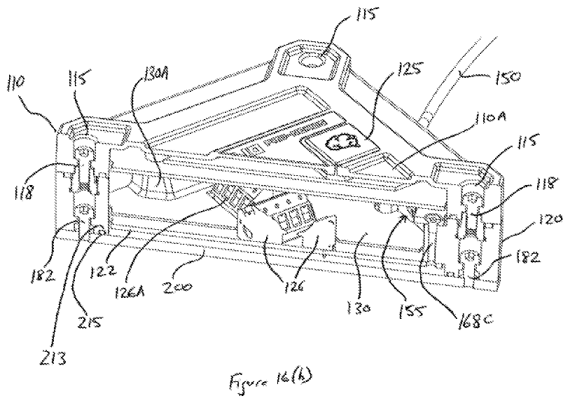

The CCM 110 is then positioned over the one logging and actuation (LAM) module 120, closing the data logger block 100 as shown in FIG. 15.

In other embodiments, as shown for example in FIGS. 75 to 77, further LAMs 120 could be included to form a stack of LAMs, these LAMs 120 being co-located within the same footprint as LAM module 120 though ‘daisy chaining’ connection is also possible. It will be appreciated that this allows a data logger system and a process control system, with which it is associated, to be modularised over time, for example as further sensors and/or actuators are included. Similarly, a data logger system including the data logger 100 may have modules removed over time, perhaps because less sensor signals require processing or actuator(s) are found to be obsolete or redundant. This could assist in prototype testing where it may be desired to monitor several sensors and/or actuators at the beginning of prototype development. As understanding of the prototyped item grows, and there is progression towards a commercial version, it may be found possible to remove sensors and logging and actuating modules associated with those sensors. The nature of controllers, whether microcontrollers or microprocessors can also be modified in the same way. This also allows simplification and cost reduction in the process control system.

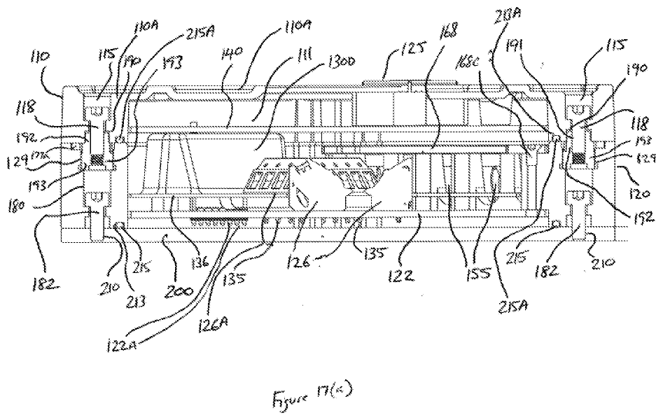

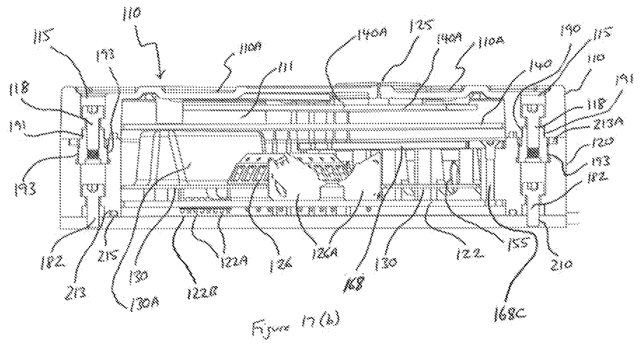

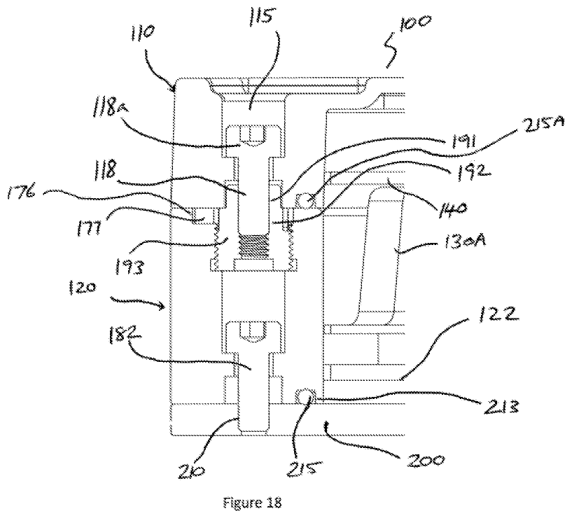

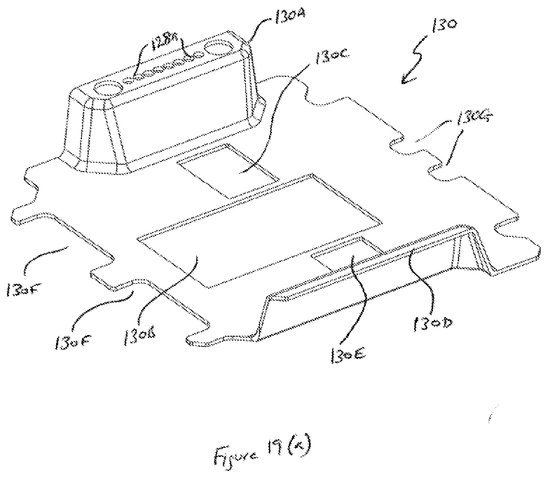

As shown in FIGS. 16 to 18, the CCM 110 is then connected to the LAM 120 by fitting screws 118 through wells 115 into the bores 191 of connectors 190. Again, this is readily achieved by a user working from above. In this embodiment, an O-ring 215A is placed within groove 213A in wall 110A of CCM 110 to provide sealing of compartment 111 and main circuit board 140 from moisture ingress. However, other sealing arrangements are possible and customised sealing components may be used, in particular to facilitate plastic moulding of CCM 110 and LAM 120.

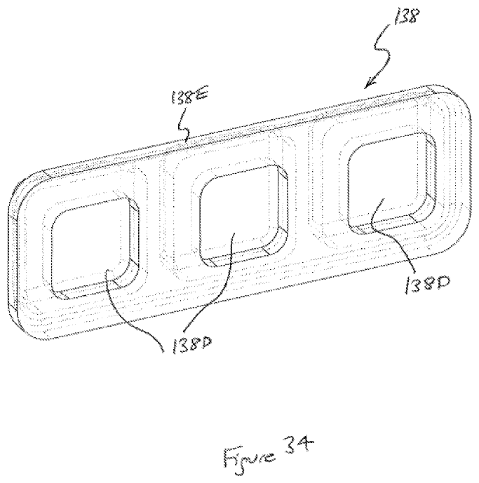

The CCM 110 in each of FIGS. 16(b) and 17(b) differs from the CCM 110 of FIGS. 16(a) and 17(b) in requiring an additional circuit board 140A. Additional circuit board 140A provides more space for components but, in particular, simplifies the combined sealing and diffuser element 238 for the top LEDs 126-129, 131 and 136, and sealing element 125A for top button 125, as shown in FIG. 36, more robust. The additional circuit board 140A, connected to the top wall by bolts inserted through holes 141A as shown in FIG. 36, is located a short distance, for example 4 mm, from the top wall of CCM 110, therefore allowing flatter sealing elements 238 and 125A to be used. This allows better sealing, also facilitating injection moulding of the CCM 110. In other embodiments, the additional circuit board 140A is not required as described below.

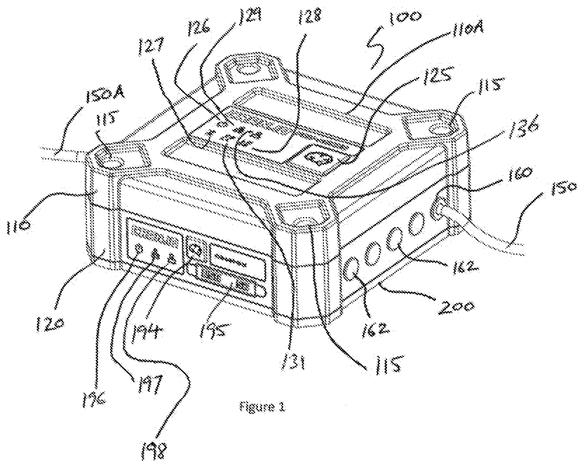

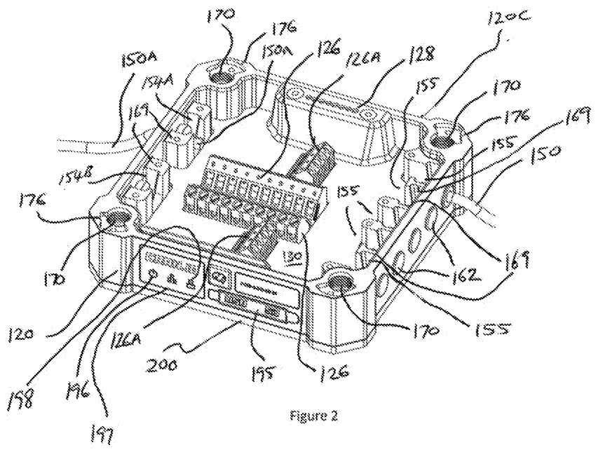

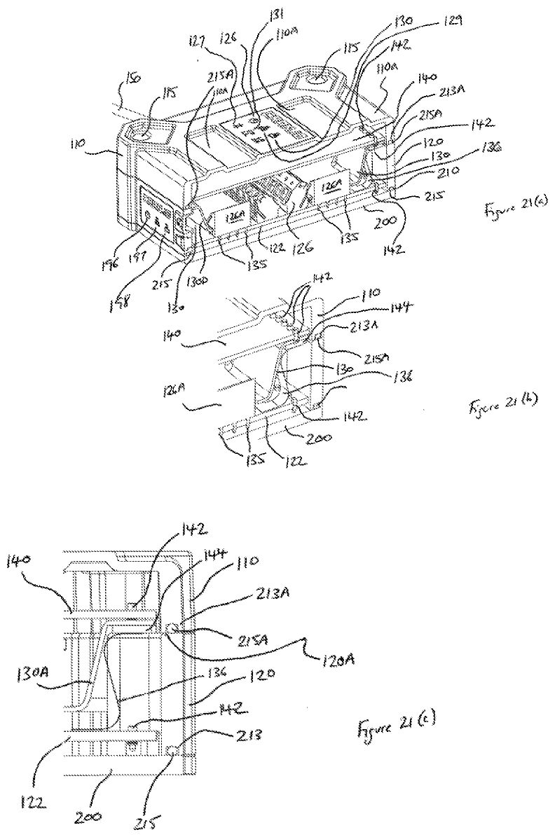

Referring to FIGS. 2, 14 and 20 to 21, the power supply to data logger 100 is an industrial 9-30 v raw power supply, provided from cable 150A (comprising ground and power wires) and port 154A-to which it is sealingly clamped as described above-through power connection block 128 on adjacent wall 120C of LAM 120. The power and ground wires are connected from power connection block 128 to the circuit board 140 of CCM 110.

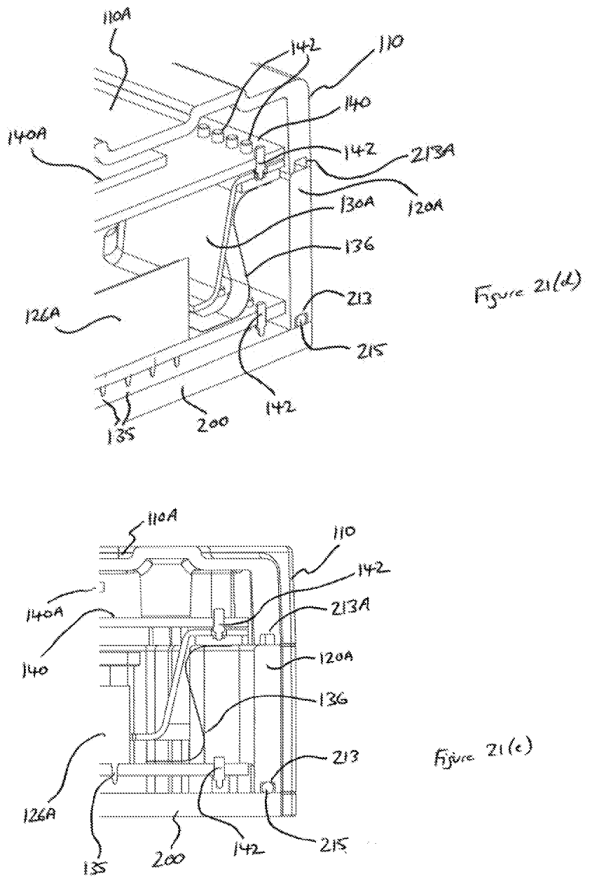

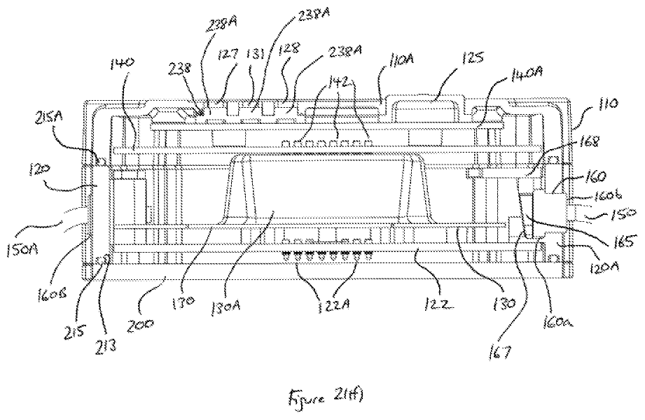

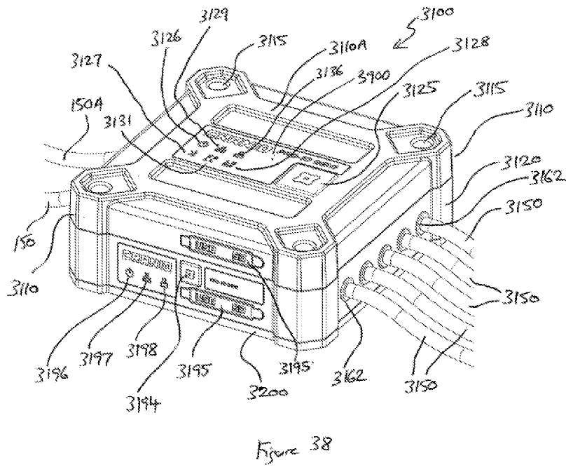

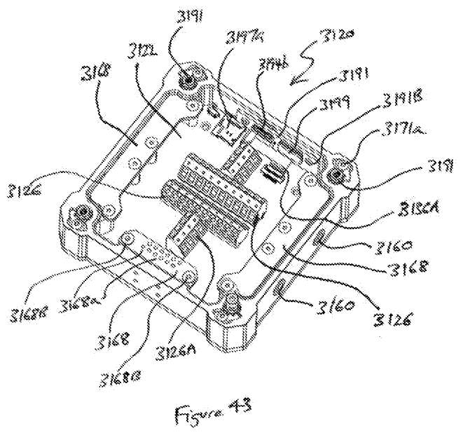

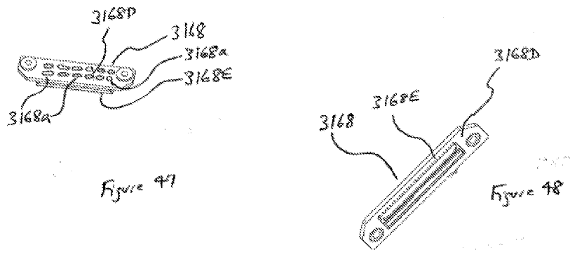

Electrical connection between the CCM 110 and LAM 120, allowing raw power to be sent from LAM 120 to CCM 110, is-in some embodiments-made by spring pin connectors 142 as shown in FIGS. 21(b) to (f), conveniently two such spring pin connectors 142. FIGS. 21(d) and (e) show the additional circuit board 140A for CCM 110 as described above with reference to FIGS. 16(b) and 17(b). As shown, the male spring pins 142 extend downward from the CCM 110 above to an array of female electrical pads 144 raised above the top surface 120A of the LAM 120. The female electrical pads 144 are shielded by the same circuit board shield 130 to ensure a user does not short any of them whilst working inside the data logger block 100 (with a screwdriver for instance). The female electrical pads 144 are connected to the main circuit board 122 by way of a multicore cable, or a flexible circuit board 136 which may connect directly to the circuit board. FIGS. 41 to 46 show an alternative connection for data logger 3100 in which the spring connectors 3142 connect to female pads 3144 and via interconnectors 3142A, 3142B and flexible circuit board 3136A to the main circuit board 3122. Interconnector 3142A is, as indicated in FIG. 48, accommodated within slot 3168E formed within the planar body 3168D of connector plate 3168 in which female pads 3168a are provided as shown in FIG. 45. In an alternative embodiment, a multicore cable connection could be used.

Further, where LAM 120 is to be connected to another LAM, spring pin connectors 122A allow electrical connection with a circuit board of that other LAM. This is achieved through pick up of female pads on the other LAM with the spring connectors 122A.

In the embodiments shown, though alternative arrangements are possible, the electrical connections provided through the above described electrical connection system for data logger block 100 are:
Industrial Power 9-30 v
CAN Communications x2 (with RS 485 communications being an alternative though at 5.0 V not 5.5V due to the nature of RS485 transceiver chips)
5.5V low power bus

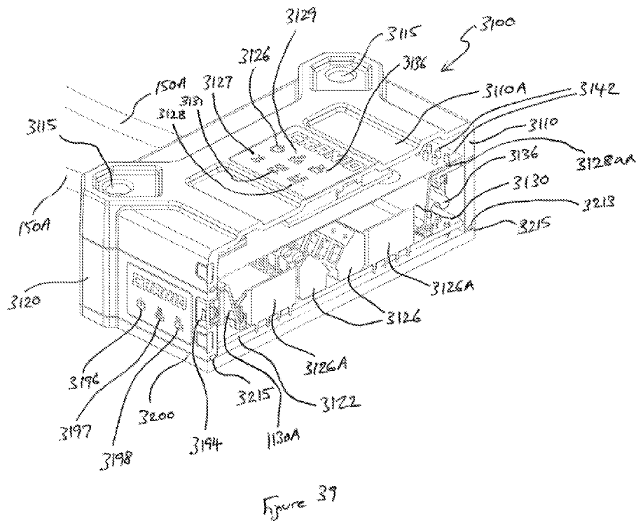

The 5.5 volt power supply from the step-down converter is then used by the CCM 110 and LAM 120 (as well as any additional LAM 120 in a stack of such modules as shown in FIGS. 75 to 77). The 5.5 volt supply is regulated to its required voltage by a step-down converter and can power up to a dedicated CAN microcontroller (a microprocessor 3199 could be used as shown in FIGS. 43, 44, 52(a) and 52(b)) located above the LAM 120 main circuit board 122 and below protective shield 130 to initiate CAN communications between LAM 120, CCM 110 and any further LAMs in the data logger block 100.

CAN communications on the CAN lines are run between the CCM 110 and LAM 120 (and any additional LAM in a stack of such LAM modules 120 as shown in FIGS. 75 to 77) on two of the spring pin connectors 142.

Either the CCM 110 or LAM 120 can utilise the raw industrial power (V_{raw}) being supplied through cable 150A for their onboard power requirements. Such power, supplied at V_{raw}, may be utilised after initial power up of the respective CCM and LAM microcontrollers by the 5.5 v supply and after communications approval from the CCM 110 microcontroller. Where power through Vraw is not available, for example due to a power outage, backup power may be sourced through a Vcom backup bus that can select power from an auxiliary (AUX) power module, examples of which are described below. The Vcom rail or bus is supplied, in embodiments, by the power protection circuit in CCM 110. Vcom supplied power to each of the CCM 110 and LAM(s) 110 in a stack.

Battery operation and use of PoE power are two examples of power supplies that can potentially provide an uninterruptable power supply (UPS) to data logger 10. CCM 110 can switch power from Vraw to Vcom and, in some embodiments, select a ‘best available’ power supply from an auxiliary power module, more than one of which may be provided. This can be done in a number of ways, for example by way of simple diodes only allowing the highest forward voltage to pass on to Vraw or by way of more complex power switching using transistors/FETs with voltage sensing.

Where more than one auxiliary power module is provided, negotiation can be between them via serial communications mediated by controller(s) as to which one provides power to the Vcom rail.

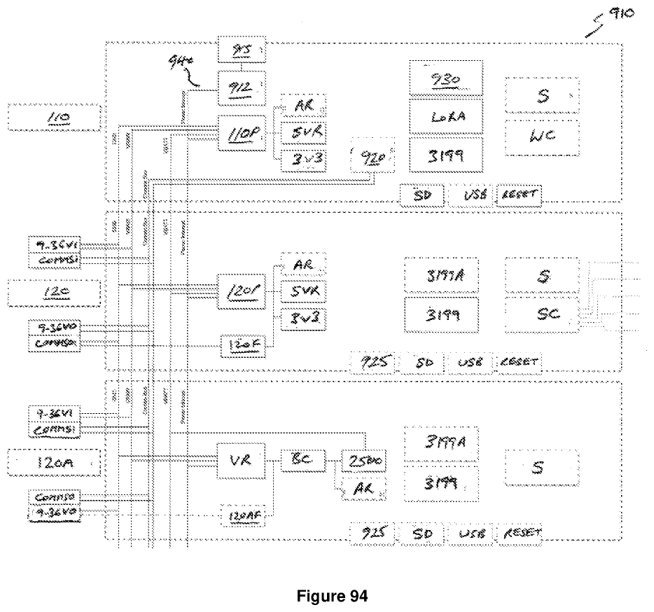

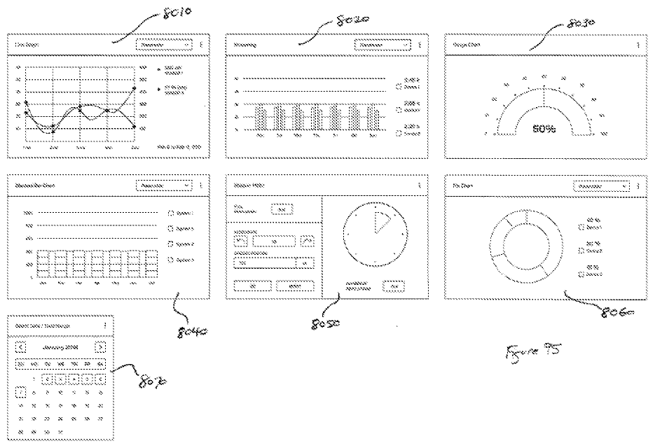

An alternative power and communications architecture which may be preferred is shown in FIG. 94 which shows the power and communications system 910 for a data logger comprising a stack of CCM 110, LAM 120 and a further LAM 120A. LAM 120A is an auxiliary power module and is capable of acting as a back up power supply allowing data logger 100 to be provided with an uninterruptable power supply (UPS). Other stack arrangements are possible and the auxiliary power module 120A does not require to be positioned at the bottom of a stack of modules.

LAM 120 is provided with a 9-36 volt industrial supply input 9-36VI as is LAM 120A. LAM 120A here acts as an auxiliary power module (AUX) provided with a battery pack 2500 chargeable by battery charger BC. While battery charger could receive energy harvested by a solar cell or similar, it is charged in this embodiment by power from the industrial supply input 9-36VI and a buck/boost regulator VR is included to regulate voltage during charging. As described above, the battery pack 2500 may be controlled by a battery management system (integrated with battery charger BC) as known in the art. Other embodiments of auxiliary power module are also possible.

LAM 120 and LAM 120A are also provided with serial communications capability and are provided with the respective inputs (COMMSI) and outputs (COMMSO) for that purpose. In this embodiment, COMMSI and COMMSO are electrically the same. A Comms bus (here CAN or RS485) allows serial communications through LAM 120, LAM 120A and CCM 110. The Comms bus terminates at Comms bus terminator 920 which includes a terminal resistor arrangement allowing the Comms bus to operate in noisy environments, for example where very long cable arrangements are used. The Comms bus may be extended out from the COMMSI and COMMSO ports for daisy chaining to other modules outside the stack. The Comms bus is electrically connected (without fusing or logic with a direct connection to the +ve and −ve rails (COMM+, COMM−) of the Comms bus.

The industrial supply 9-36VI supplies the power rail Vraw during normal conditions, i.e. where that power supply is available. The Vraw rail with ground rail (GND) supplies voltage to each LAM 120, LAM 120A and CCM 110. As described above, CCM 110 allows voltage regulation to 5 v or 3.3 v through voltage regulators 5VR and 3v3. The same provision is also made for LAM 120. If provision by a specific charging system is included, it may also be necessary to include ancillary voltage regulators (AR).

In LAM 120A, acting as auxiliary power module, the buck/boost converter VR is simply required for regulation of voltage to battery charger BC so the regulators 5VR and 3V3 are not required other than in circumstances as described below.

As to fuses 120F and 120AF, an electronic fuse, conveniently a silicon based e-fuse is respectively included in LAM 120 and LAM 120A. Traditional fuses, of wire or re-settable type, would typically be slow to switch-out the connected power rail and their characteristics are also affected by environmental temperature. A secondary connected system, powered through the data logger stack (by stacking or daisy-chaining) could potentially cause power failure of the whole system 910 in the event of a fault within the overall system. The electronic fuses 120F and 120AF provide fast and configurable protection, disconnecting faulty circuits. Since no physical fuse is present, no part replacement is required following a fault and simple re-set (or automatic reset) enables full system operation once the fault is removed. The e-fuse can also be a system end-point allowing the data logger (through LAM 120 or CCM 110) to provide feedback to a user as to the fault that occurred.

Power and communications system 910 further provides a battery power rail (VBATT) which is capable of supplying battery power from battery pack 2500 to each of LAM 120 and CCM 110.

CCM 110 and LAM 120 are provided with respective power prioritisation controllers 110P and 120P which have circuitry to enable automatic or instantaneous transition to a back up or secondary power source, here the battery pack 2500 of LAM 120A. The power prioritisation controllers 110P and 120P are configured such that the 9-36 v industrial supply (9-36VI) is the preferred power source and a transition to back up power from battery pack 2500 is executed outside the 9 to 36 v voltage window. All instances of power prioritisation are intended to include over-voltage protection to protect the following circuitry from external voltage transients.

As to ‘primary’ microcontrollers 3199 for CCM 110 and LAM 120, these are as previously described. However, in this embodiment, LAM 120A is ‘dumb’ having no function beyond acting as an auxiliary power module and no microcontroller is included. As such, primary and secondary microcontrollers 3199 and 3199A of LAM 120A are shown in dashed outline. However, LAM 120A may also be a smart device on implementation of primary and/or secondary microcontrollers 3199, 3199A. In this case, the 5VR and 3V3 voltage regulators and, if necessary ancillary voltage regulators AR, would also be included in LAM 120A.

CCM 110 is further provided, in this embodiment, with a secondary microcontroller 930. This is an optional component, being required if the CCM primary microcontroller 3199 does not have additional communications, such as Bluetooth, for configuration of the device. Secondary microcontroller 930 is also included if primary microcontroller 3199 cannot update its own firmware without the interaction of the secondary microcontroller 930.

In the embodiment shown, the connections between the secondary microcontroller 930 and primary microcontroller 3199 include:
Serial communications (UART/USART, or SPI, or I2C)
Reset primary microcontroller
Erase primary microcontroller (optional, may be omitted)

The Bluetooth module of secondary microcontroller 930 includes an ARM Cortex processor which controls Bluetooth communications external to the primary microcontroller 3199. In the event of an over-the-air firmware upgrade, the secondary microcontroller 930 may receive new firmware, storing it in dedicated FLASH memory chip connected to the secondary microcontroller 930 before reflashing the primary microcontroller 930. The secondary microcontroller 930 can retain multiple copies of the firmware for the primary microcontroller 3199. It can also act as a ‘watchdog’ and intervene by ‘Resetting’, ‘Erasing’ and ‘Reflashing’ the primary microcontroller 3199 with appropriate firmware when required. If required, the secondary microcontroller 930 can revert to the original default firmware that was originally functioning on the primary microcontroller 3199, for example if a malfunction is detected.

In other embodiments, the functionality of the secondary microcontroller 930 or 3199A may be integrated with the functionality of the primary microcontroller 3199.

System 910 is also provided with functionality to provide a power interrupt signal, through power interrupt bus 940, to all of the stacked CCM and LAM modules 110, 120 and 120A. This bus enables the CCM and LAM modules to enable/disable their operation based on the push button controller 912 state, in turn determined by the user's pressing or not pressing push button 915 (externally available to the user through the casing of CCM 110) or push buttons 925 of LAMs 120 and 120A (externally accessible to the user for the LAMs 120 and 120A.

The push button controller 912 state may be controlled by the push button controller 912 itself or by microcontroller 3199. In embodiments, the push button controller controls the turning on of the device when device is not already powered on. The push button controller 912 may enable a state where it passes on momentary presses to the microcontroller 3199 as an input (and hence can be used as a binary sensor input end-point).

The push button controller 912 may also be enabled to detect a long hold press and pass off a different electrical signal, either directly to shut down the power regulators of the entire stack as part of the power prioritisation control system 110P, 120P or to the microcontrollers 3199, 3199A, 930 in the stack to enable a controlled shutdown.

As to operation of the UPS system, if zero voltage is detected in the Vraw rail (conveniently through the battery management system integrated within battery charger BC though seamless control through, for example, microcontroller 3199 of LAM 120A is also possible with logic included for system protection, e.g. microcontroller 3199 of LAM 120A may cut power to the system 910 if battery voltage falls too low or temperature increases above a threshold), the microcontrollers 3199 can switch the power source to battery power from battery pack 2500 through the VBATT rail acting in conjunction with the GND rail. The desired powering state, in this embodiment, is the industrial 9-36 v supply. Thus, if that supply is available, the microcontrollers 3199 drive Vraw to supply power accordingly. However, in other embodiments, this could be reversed.

The configuration of each module 110, 120, 120A is-in terms of memory (SD and USB), reset (RESET) functionality and on board sensor(S) capacity and sensor interface circuitry (SC), the same as previously described. CCM 110 is also provided with serial wireless communications (WC) capability through a LoRA or other long range transmission protocol.

A connection can be made between adjacent LAM 120, CCM 110 and AUX power modules so that the data logger 100 can know the order that the LAM blocks 120 are in the stack so that a visual representation of the system can be derived automatically and indicated to the user by mobile or web based application as described further below. The connection could take the form of a single ended 3.3 v direct to the microcontroller 3199, current limited, connection allowing the data logger 100 to understand the stacking order of LAM blocks 120 via CCM 110. Confirmation and communications are through the communications bus. A spare connection may be provided for.

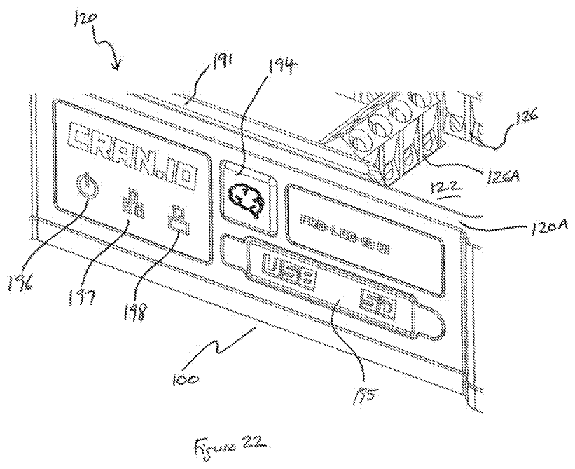

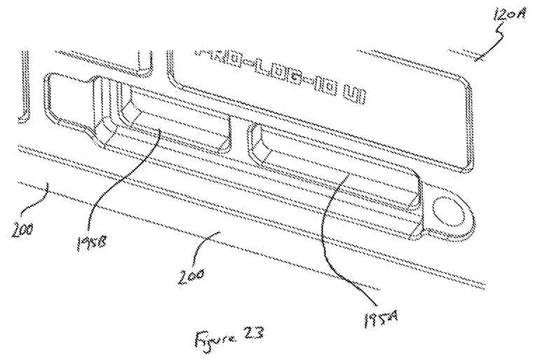

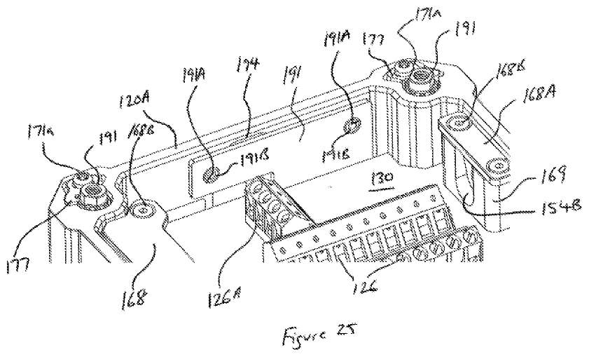

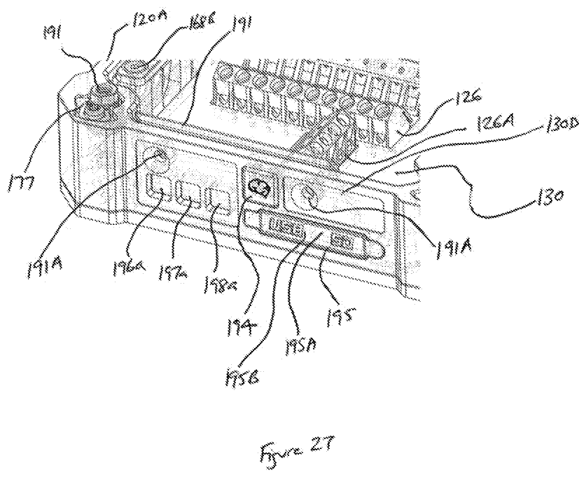

As shown in FIGS. 22 to 28, each LAM 120 has, as accessible memory, its own removable SD Card (not shown) on the main circuit board 122 for configuration and logging of high-speed sensor and/or actuator or other end point data. LAM 120 is also provided with a USB-C connector to be used to power up the LAM microcontroller (mounted on the main circuit board 122 and shown for the second embodiment, FIG. 50, as item 3199) for performing computations and communications and access to the SD Card only to offload the contents of the SD card via wired USB to, for example, a suitable computing device. The SD Card and USB-C connector are accessible through the SD Card port 195A and USB-C port 195B via the front sealing flap 195 on the front wall 120A of the LAM 120 as shown in FIG. 23. A further embodiment of front sealing flap 3195, though having generally similar function to front sealing flap 195, is described below with reference to FIGS. 57 to 59. Further microcontrollers or microprocessors could be included to perform specific functions for a LAM 120 but these would interface with the primary microcontroller or microprocessor as described above. The primary microcontroller or microprocessor would do the bulk of the communications, logging and control for such a LAM.

Use of SD Card and USB-C connector for storage and transfer of data from data logger block 100 allows avoidance of streaming of data which can constrain a data logging system. However, data logger block 100 may be enabled to stream data as well, if necessary.

The front of the LAM 120 is also provided with a button 194 and three RGB LED illuminated lamps 196, 197 and 198 for interaction and feedback to the user, with a range of information being communicable through different light colour (colour across the visible spectrum is provided), flashing and/or strobing routines. The RGB LEDs are respectively assigned to Power Status 196, CAN Communications Status 197 and Bluetooth communications. An additional LED 198 is also provided. Button 194 and LED 198 may be user configurable (i.e as at least one user configurable input and at least one user configurable output) to allow user actions and provide information based on the data acquisition, processing and/or control strategy in which data logger 100 is used. Alternatively, LED 198 may be used to provide status for an additional wireless communications protocol. More than one user configurable button and LED may be provided.

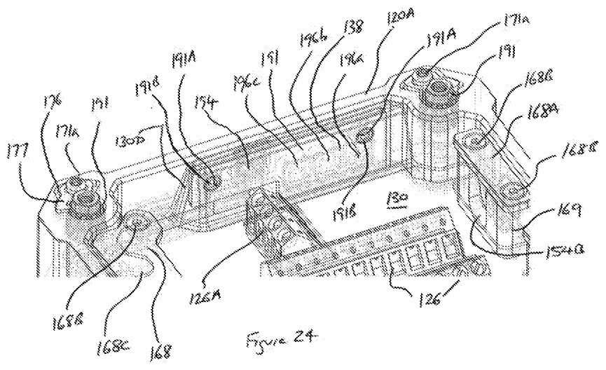

The LEDs 196-198 reside, as shown in FIGS. 24, 25 and 27 to 29, on the front circuit board 191, screwed into wall 120A of LAM 120 by two countersunk bolts 191A, for example of M3 type, the boss 191B of each of which is soldered into front circuit board 191, which fit through threaded bores 191A (one of which is shown in FIG. 29 and which allow clamping and sealing into place of an optically transparent or opaque silicone seal and diffuser 138 for the RGB LEDs 196-198 to emit out through square holes 196a-198a in the front of the LAM wall 120A and illuminate the overlay sticker provided with icons showing the function of each LED 196-198. Portion 130D of circuit board shield 130 provides protection for the front circuit board 191 and the RGB LEDs 196-198. FIGS. 52(a) and 52(b) show more detail of the front circuit board 3191 which, though for the second embodiment, is the same as for the presently described front circuit board 191 with threaded bores for connecting bosses (not shown) being labelled 3191A. The button mounting 3194A is mounted on the front of the front circuit board 3191 shown in FIG. 52(a) as are RGB LEDs 3196-3198 which interface with flexible circuit board 3136A. Microprocessor 3199 and button circuit 3194b are mounted on the rear of the front circuit board 3191 as shown in FIG. 52(b).

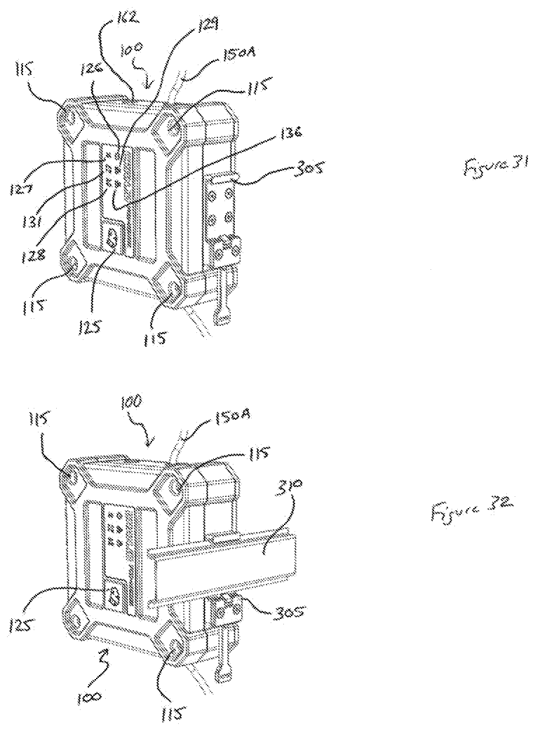

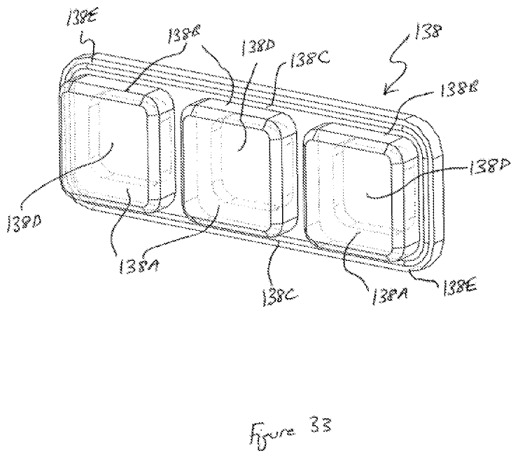

Silicone seal and diffuser 138 is provided as a single sealing part, as shown in FIGS. 33 and 34 which is provided with sealing surfaces 138B formed on projections 138A each protruding through respective square holes 196a-198a for providing sealing at the holes. Sealing surfaces 138C provide sealing at the inside face of wall 120A of LAM 120 and at the front face of the front circuit board 191. Cavities 138D allow for LEDs to be placed on the front circuit board 191 that shine out through the sealing part, and more particularly projections 138A, through the square holes 196a-198a for illumination as described above. A sealing rib 138E running around the front edge of the sealing part 138 is provided to ensure contact with wall 120A and sealing around the sealing part 138.

As shown in FIG. 36, a similar silicone seal and diffuser 238 is provided for the LEDs of the CCM 110. Here. sealing surfaces 238B providing sealing where projections 238A protrude through the holes 126-129, 131 and 136 for directing light from the CCM LEDs.

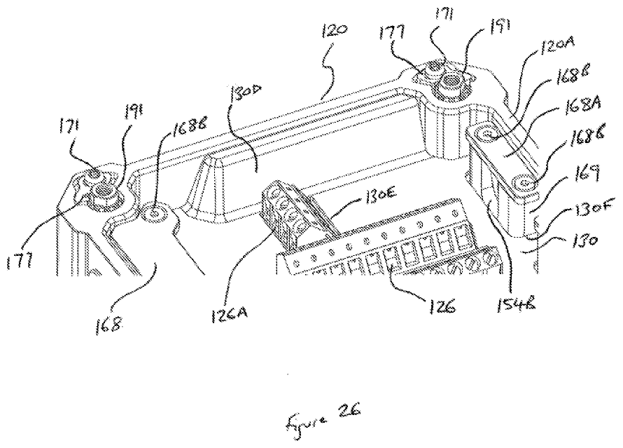

The button 194, as shown in FIGS. 27, 28 and 34, is protected from water and dust ingress, again optimally to an IP68 rating, by a silicone seal and physical cover 194A protruding through the outer wall 120A of LAM 120. A user presses button 194 for interaction with the LAM 120 of data logger block 100. Button 194 is connected to the main circuit board 122 by a multi-core cable or a flexible circuit board. For button 3194 of data logger 3100, shown in FIG. 37, button 3194 is—as shown in FIG. 51—connected to main circuit board 3122 by a flexible circuit board 3136A extending from a block 3194A, connected to button 3194, to block 3136B electrically connected to main circuit board 3122.

The CCM 110 is made, in embodiments, from an impact and UV resistant plastic though aluminium may be preferred when external antennas are used such that no internal RF antennas require RF line of sight from CCM 110. CCM 110, as shown in FIG. 21(a), has a button 125 and six indication RGB LEDs 126-129, 131 and 136 utilising the same silicone circuit board sandwich sealing system, as described above for both the LEDs 126-131 and the button 125. As with LAM LED 198, LED 130 at least may be configured by a user to a specific purpose. LED 130 may conveniently be an output actuator indicating a value of a sensor signal, whether before or after processing—including by transformation or calculation—as described below. In this case, LED 136 could function as an alarm, advising a user if a parameter sensed by the sensor is beyond permissible bounds.

The primary purpose of CCM 110 is as controller and communications mechanism with a user as well as to enable CAN communications with each LAM 120 in a stack. Wireless communications are provided and a number of protocols including Bluetooth (BLE), cellular wireless communications (CELL), LoRa low-power wide area network (or all of these) may be provided for as indicated by icons 127, 128 and 131. In other embodiments shown, Bluetooth (BLE) alone may be has selected to allow the user to interface with the CCM 110 and data logger 100 via a smartphone, tablet or other communicating device via Bluetooth app. A Bluetooth chipset is therefore included within LAM 120. Other forms of communication including a wired connection, for example an Ethernet connection, could also be provided for. In such embodiments, the function of LEDs 127, 128 and 131—which are not needed for wireless communications—may be defined by the user.

CCM 110 also includes a microprocessor for hosting a state machine and setting up tasks when configured by a user. A state machine approach—whether using deterministic or non-deterministic state machines—is preferred for control systems using the data logger 100 of present embodiments.

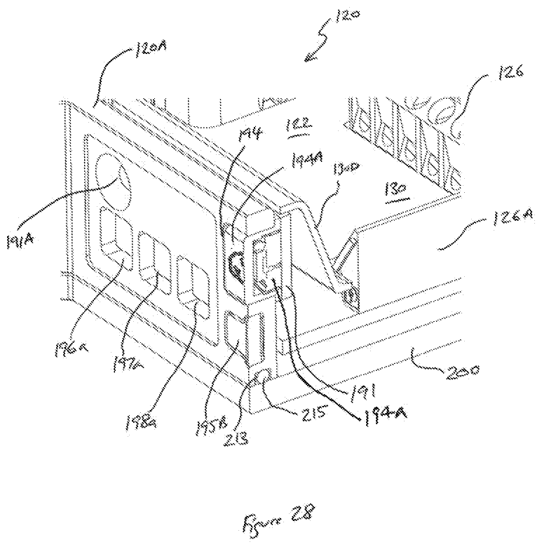

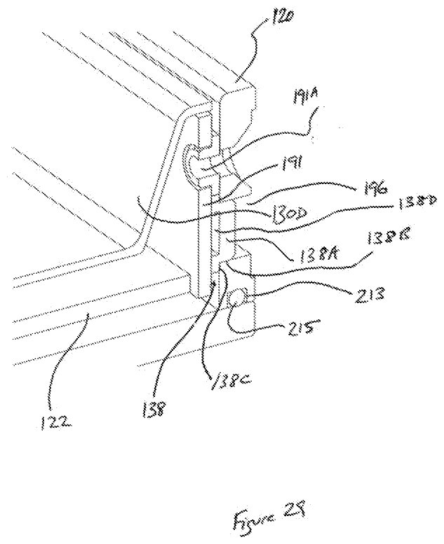

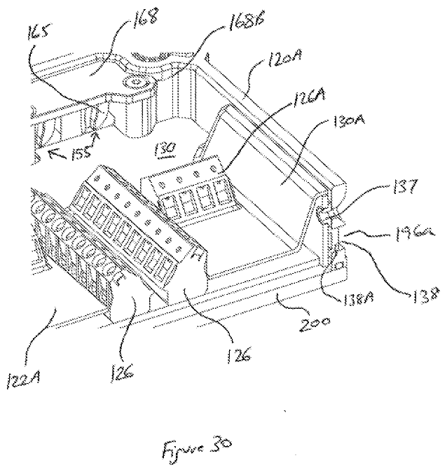

In a further embodiment, an array of blind holes may be provided in the back of the LAM 120 to facilitate other mounting options for a data logger block 100 comprising a stack of LAMs 120. Further, a proprietary DIN mount system could be included in LAM 120 so that the data logger block 100 can be mounted inside industrial enclosures. FIGS. 30 and 31 show an embodiment in which the data logger block 100 is provided with a mounting bracket 305 that can be fitted on to DIN rail 310 forming a mounting point for data logger block 100.

In some cases, an industrial power supply—such as the 9-30 volt supply described above—may not be available. In such cases, other powering options are available, including battery powered and energy harvesting or Power over Ethernet (POE) which allows transfer of both power and data through a twisted pair cable system. Such powering options are conveniently provided through an auxiliary power module, conveniently having the same form factor as LAM 120, 2120, 3120.

As shown in FIGS. 73 and 74, a LAM 2120 (acting as an auxiliary power module) may, for example, be provided with 3 18650 lithium batteries 2500 connected in series to power the data logger. Such an arrangement would provide up to 2 Amps of power at 11.1 volts. The batteries 2500 may be rechargeable, being supplied with power from a single solar panel (not shown) wired through the cable sealing and clamping system. Onboard battery management, including an MPPT system for drawing the maximum power from the solar panel to enable charging of the batteries through a battery charging circuit. A fuel (state of charge or SOC) gauge would also be included for battery balancing and accurate power consumption and run time estimations. Solar power could also be used directly as a power supply for data logger 100 with power supply being automatically switched to battery supply by the CCM 110 control system when solar power is not available.

LAM 2120 may be connected with other LAM(s) 120 through a CAN communications system as described above.

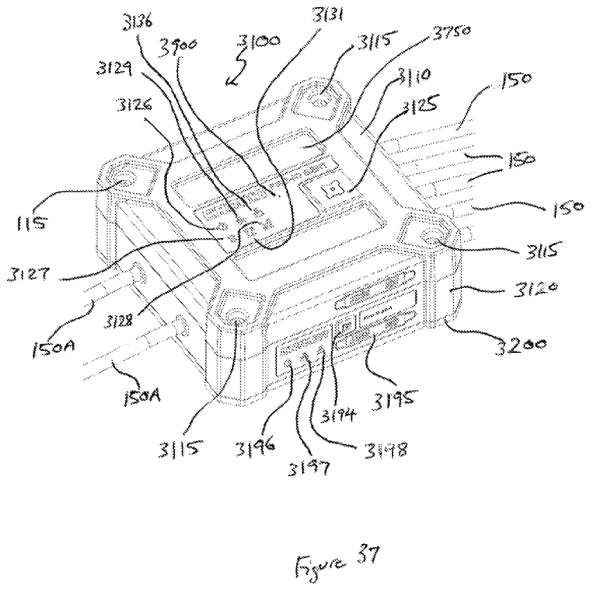

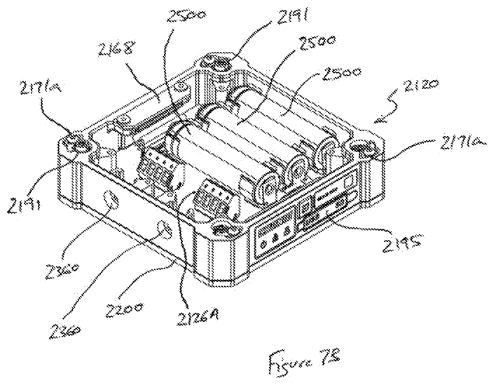

Further embodiments of data logger 3100 are shown in FIGS. 37 to 72. Data logger 3100 is similar to data logger 100 as already described and the reference numbering is, unless otherwise provided, the same but for the prefix “3”. Data logger 3100 allows connection of sensor and actuator cables 3150 through either clamping and sealing connectors as described above or with standard connectors as illustrated in FIG. 71. It is also possible to use single clamping or connector plates 3168 on both sides of the data logger, as shown in FIGS. 40 to 48, rather than two clamping plates 168A on the power connection side as described above. Data logger 3100 is, without limitation, suitable for applications requiring sensing of air pressure or quality for which a port 3900 allows air to access an in board mounted barometric pressure sensor 3930. Other sensors such as gas composition sensors or air quality index sensors could alternatively, or additionally, be included.

As shown in FIGS. 56 to 58, front sealing flap 3195 is provided with outer ribs 1195a to provide sealing at the USB and SD card slots 1197a and 1198a of the LAM 1320 with one main outer rib 195a to seal the outer opening and two secondary seals 1195b to seal the USB-C port 3195B and SD Card port 3195A. The sealing flap 3195 also has a section 1197 that extrudes into the USB-C port 195B to provide additional sealing to the USB-C port 3195B via interference fitting. A shorter extension 1198, serving the same function, is provided for SD card port 3195A.

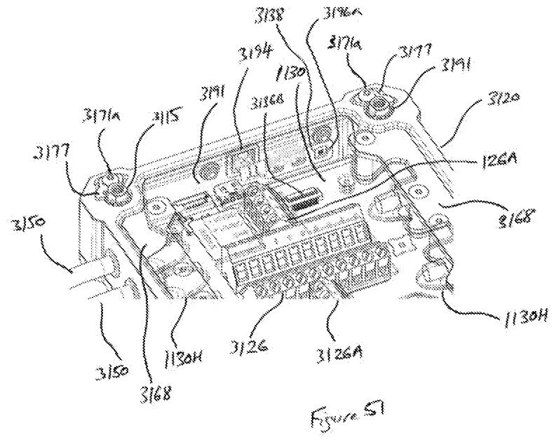

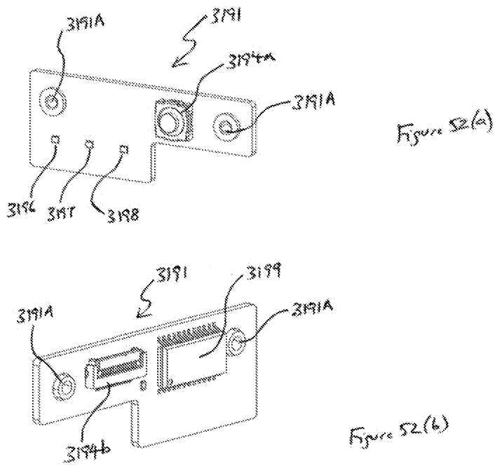

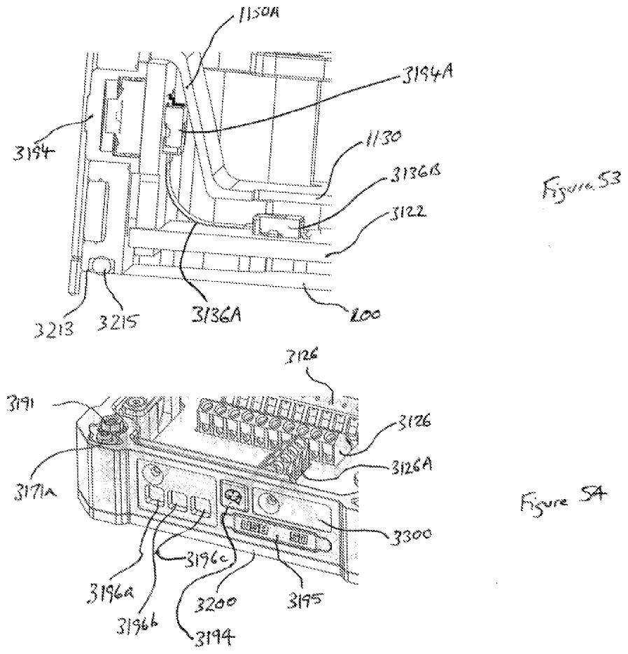

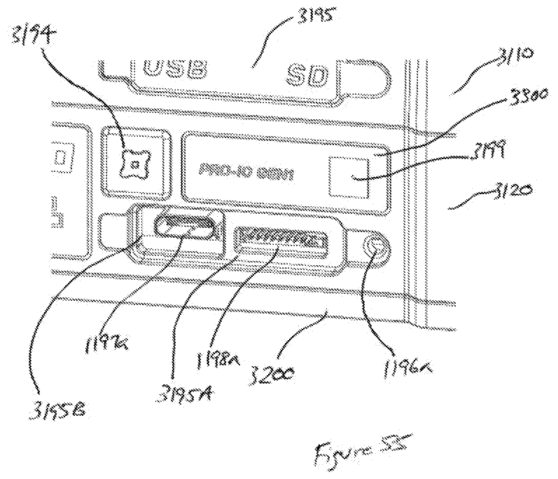

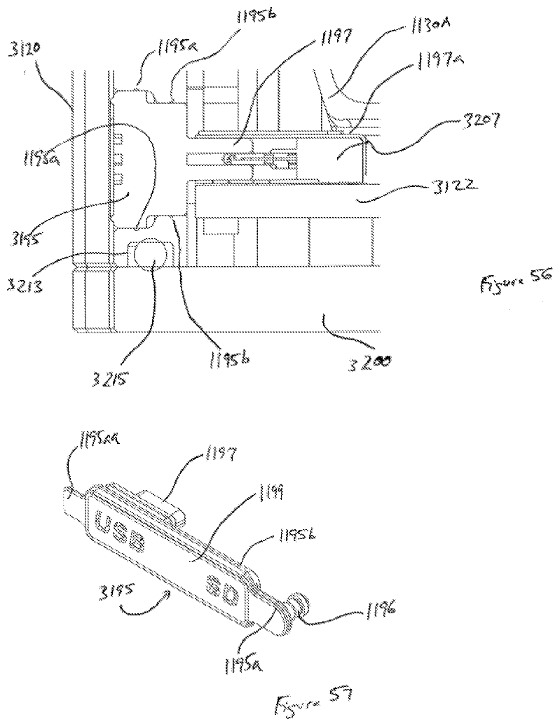

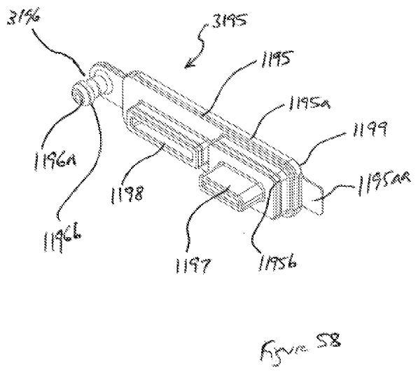

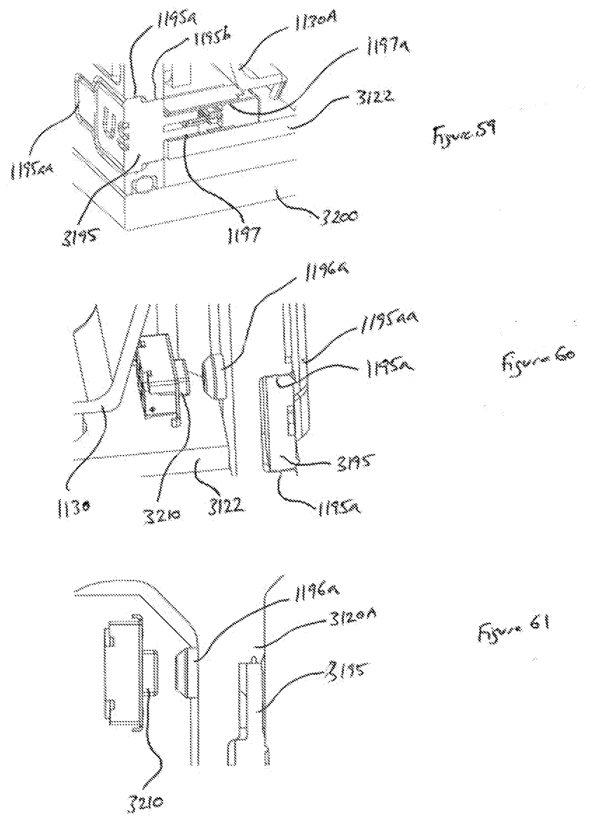

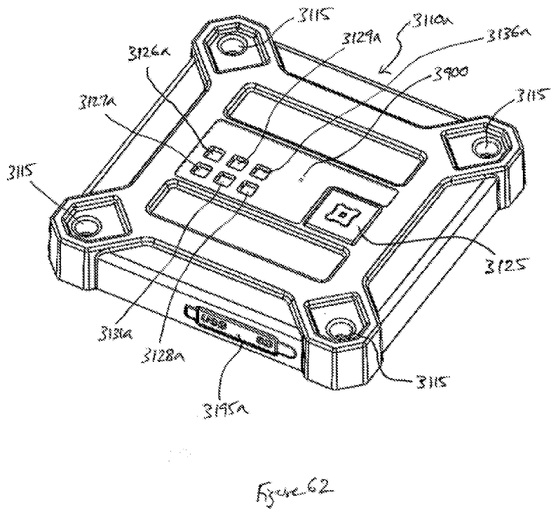

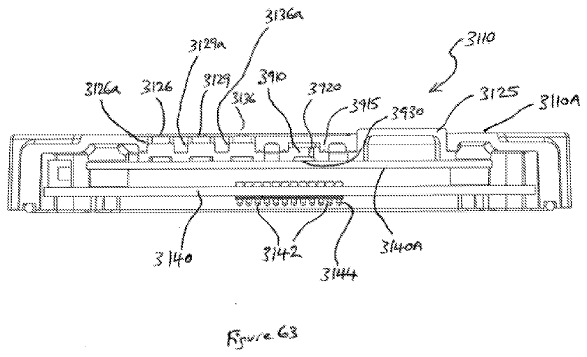

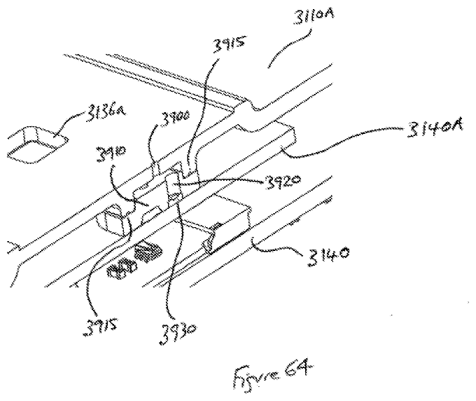

Front sealing flap 3195 is removable though needs to be secured to the LAM 3120 when in use. An insertion tip 1196, together with the sealing arrangement described above and central sealing rib 1196b, assists with such securement. The insertion tip 1196 is desirably provided with a partly flexible portion 1196a to enable insertion and securement and a hole to enable ready removal. Removal of the front sealing flap 3195 also allows access to a reset button 3210 as shown in FIGS. 60 and 61. Reset button 3210 allows a hard reset of the LAM 3120 allowing for re-configuration, where required.

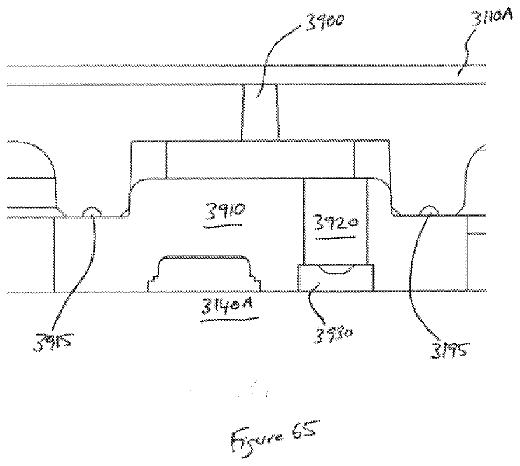

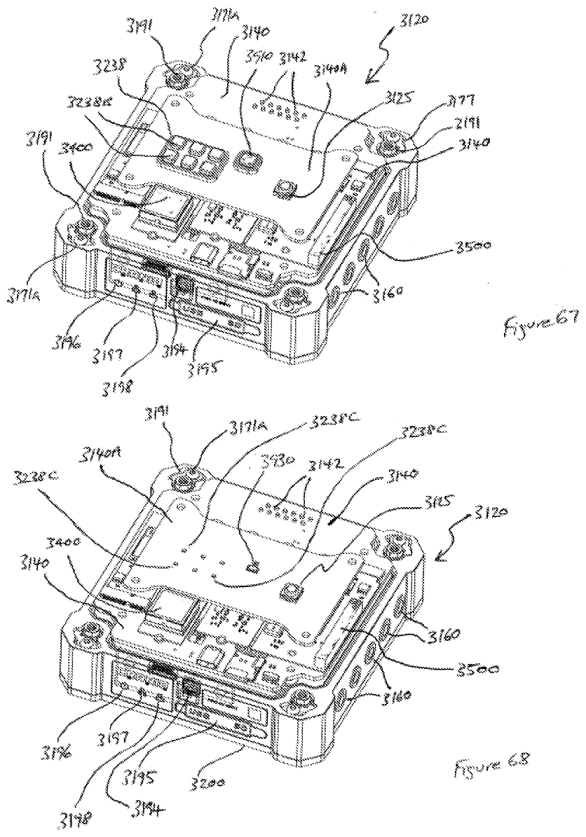

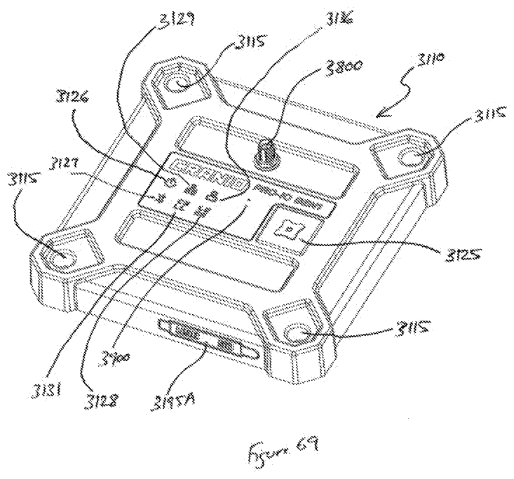

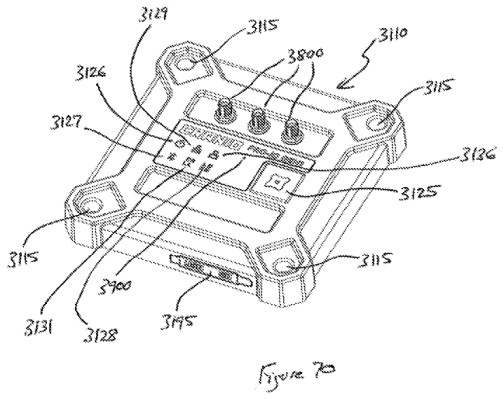

Referring to FIGS. 63 to 65, the sensor 3930 is connected to the CCM circuit board 3140A with sealing required from the remainder of the CCM 3110. To this end, port 3900 communicates with sensor 3930 through a small passage 3920 to allow air ingress to sensor 3930, for example a barometric sensor or air quality index sensor though other sensors are not precluded. A seal 3910 keeps such air away from the remainder of the CCM 3110 with sealing ribs 3915 compressing against the inner surface of the top wall 3110A of the CCM 3110 to complete the seal. The seal 3910 utilises the same sort of silicone circuit board sandwich system as for the LEDs 126-129, 131 and 136 and top button 125. Referring to FIGS. 66 to 68, the three circuit boards 3122, 3140 and 3140A are shown in conceptual form. It will be appreciated that the electronic configuration of a data logger 3100, or other embodiments thereof, can vary significantly dependent on the application to which it is put. However, in addition to an onboard sensor 3930 as above described, a position sensor 3400—in this case a surface mounted active GNSS sensor as available from Taoglas, for example under part number ASGGB184.A—is provided on circuit board 3140. An inboard mounted wideband antenna 3500 is also provided, for example the Warrior PA.710.A wideband 4G/3G/2G SMD PFIA as also available from Taoglas. FIG. 67 shows the LED diffuser 3238B in place together with seal 3910 for the air sensor and the seal of CCM button 3125. FIG. 68 shows the RGB LEDs 3238C for the CCM 3310 as well as the air sensor 3930. The light from the RGB LEDs 3238C is transmitted through slots 3126a, 3127a, 3128a, 3129a, 3131a and 3136a (as shown in FIG. 62) to be transmitted through diffuser portions 3238B of diffuser 3238 as shown in FIG. 67.

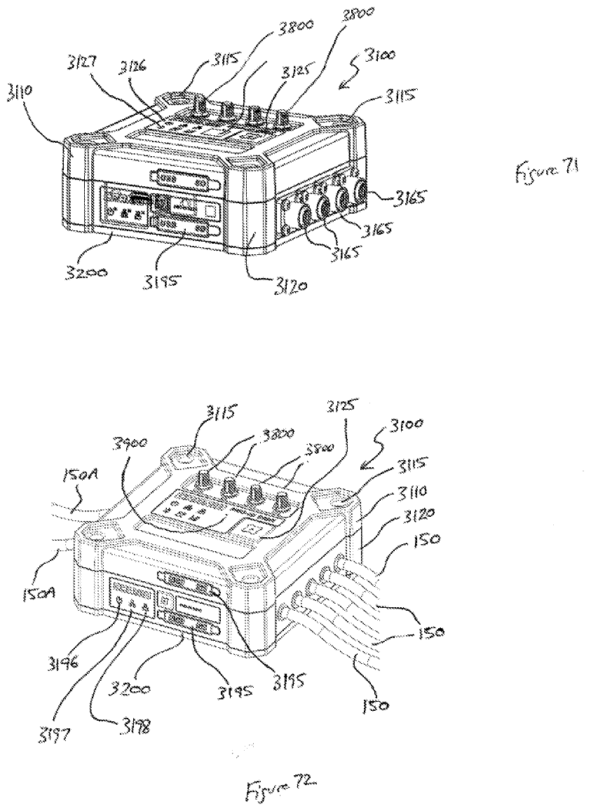

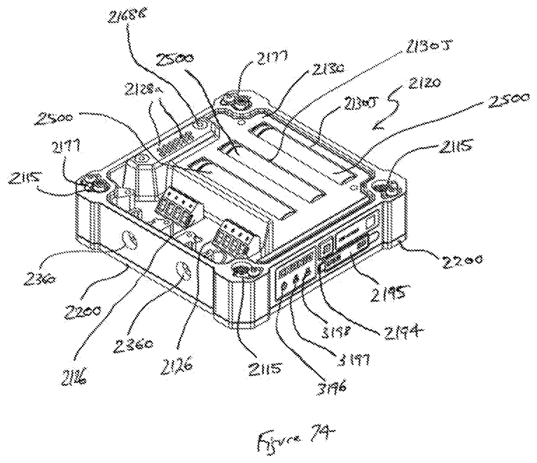

As described above, inboard antennae can be fitted inside the CCM 110 allowing wireless communications with the data logger 110. External antennae 3800 can also be fitted through cut outs 3802 in the circuit board 3140, as shown in FIG. 66, for increased wireless range if required. Such external antennae 3800, which extend through the top surface 3110A of CCM 3110, may be of the form known in the art and obtainable commercially. Any desired number of antennae 3800 can be adopted, conveniently at the option of the user. FIG. 69 shows a CCM 3110 with one external antenna 3800. FIG. 70 shows a CCM 3110 with three external antennae and FIGS. 71 and 72 show a CCM 3110 with four external antennae, respectively corresponding to Bluetooth, LORA, cellular and user assigned wireless communications protocols.

The antenna system for the CCM 3110 may be Multiple-In Multiple-Out (MIMO) dual antenna systems. The dual antennae allow asynchronous transmission and reception of radio signals on slightly different radio signals on slightly different radio frequencies. This facilitates higher throughput and integrity of data.

Referring to FIG. 78, there is shown a further embodiment of data logger 4100 which has similar appearance to the data logger 100 shown in FIG. 75. The various components of data logger 4100 have the same functionality as provided in data loggers 100 and 3100 as described above and the reference numbering is, with the addition of the numeral prefix “4”, generally the same as provided above.

Data logger 4100 comprises a CCM 4110 and two LAMs 4120 and 4120A. LAM 4120A is the top LAM connected to CCM 4110 and lower LAM 4120. CCM 4110 has four external antennae 4400 in the form of SMA connectors.

Mechanical connections between each of LAMs 4120 and CCM 4110 are made as above described, with reference to FIGS. 8, 12 and 13, by installation of connectors 190 and retaining combs 177 within wells 170 and comb retainers 176 provided at each corner of each LAM 4120. Similarly, and as shown in FIGS. 16 to 18, the CCM 4110 is connected to the top LAM 4120A by fitting screws 118 through wells 115 into the bores 191 of connectors 190. Further description of mechanical connection between CCM 4110 and LAMs 4120 and 4120A is provided above.

However, electrical and communications connections between LAMs 4120 and CCM 4110 are simplified from the electrical and communications connections of the above described embodiments. Spring pin connectors 142 are replaced with vertical printed circuit boards 4130. This may ensure more reliable electrical connection and also avoids requirement for a flexible circuit board or multicore cable for connection of the LAM circuit boards 4122 and CCM circuit board 4140. The LAM circuit boards 4122 are located a fixed height above the LAM base 4200 as indicated by the O-ring groove.

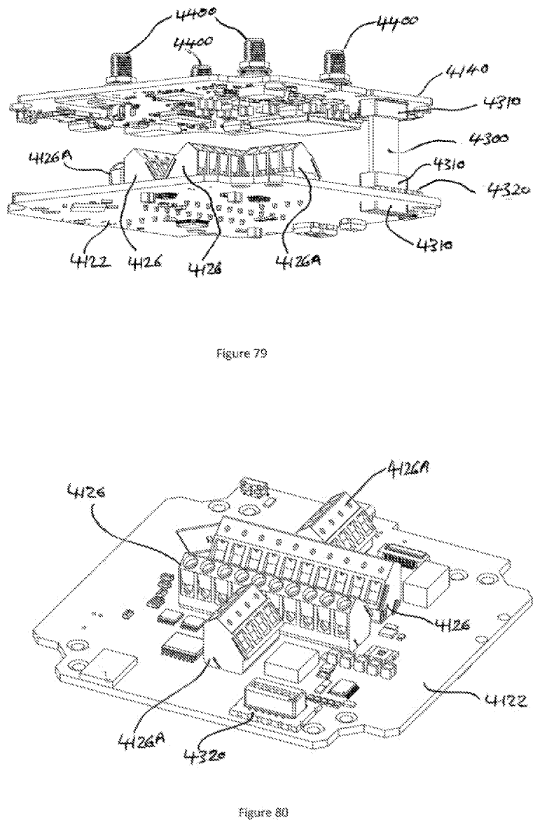

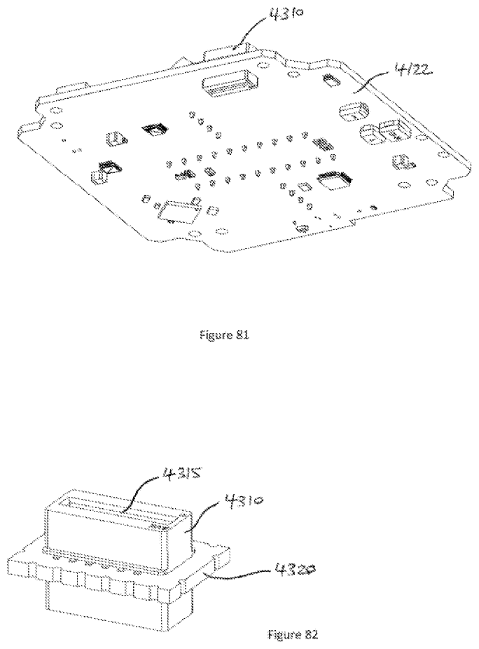

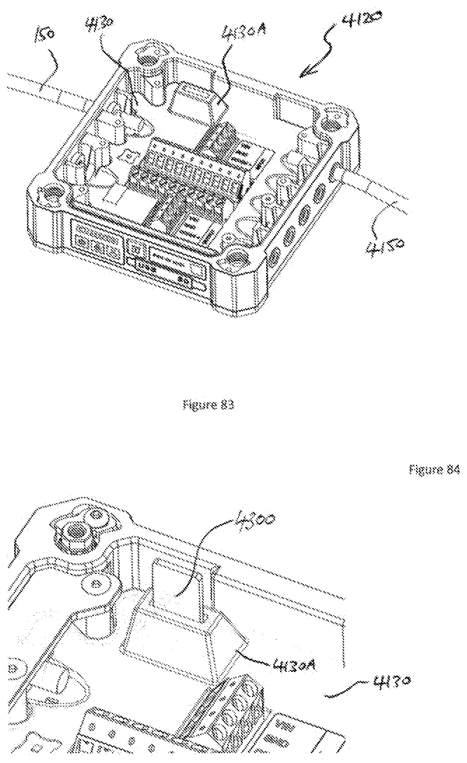

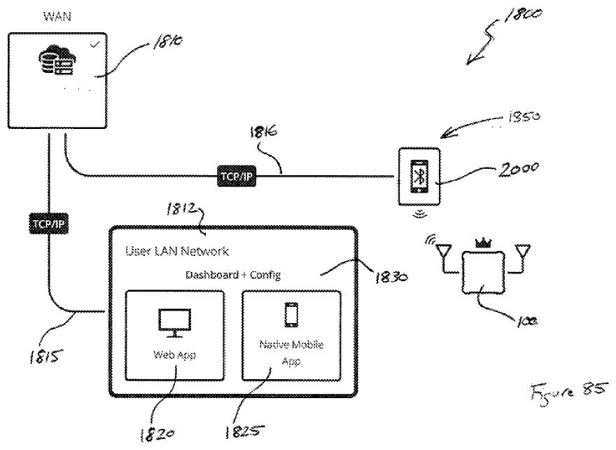

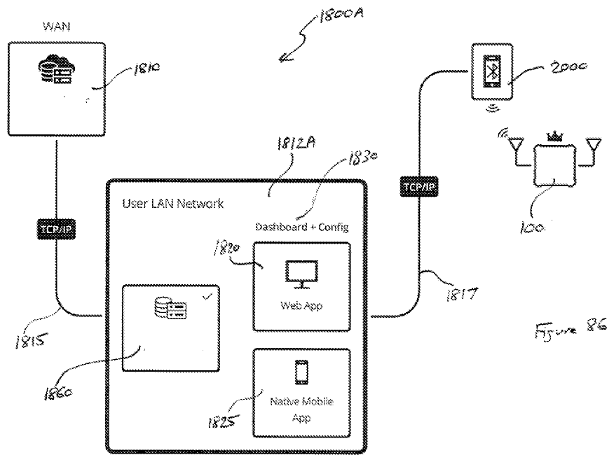

As shown in FIGS. 79 to 81, CCM circuit board 4140 and LAM circuit board 4122 are fitted with circuit board connectors 4310 with a desired number of plated contacts, for example 10 or 20 though the number is flexible. Suitable circuit board connectors 4310, one being shown in FIG. 82, may be sourced from Kyocera under the AVX brand. Circuit board connectors 4310 are electrically connected to the respective CCM and LAM circuit boards 4140 and 4122 through carrier boards 4320.

Vertical printed circuit board (PCB) 4300 is located in electrical and communications contact with the circuit board connectors 4310 through the carrier boards 4320. Vertical PCBs 4300 connect the bottom LAM circuit board 4122 to the top LAM circuit board 4122; and the top LAM circuit board 4122 to the CCM circuit board 4140.

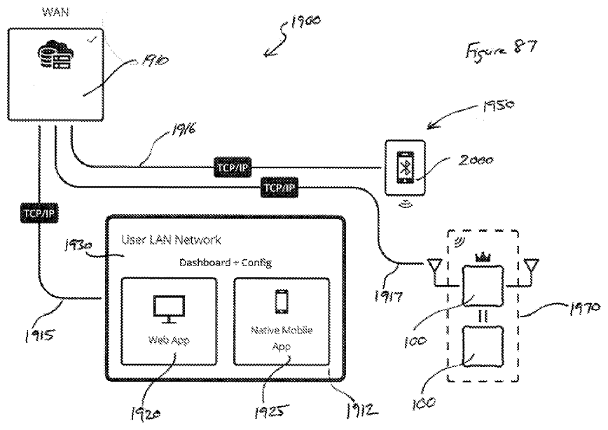

Referring to FIGS. 83 and 84, the use of vertical PCBs 4300 requires a modification to the plastic insulating shield 4130 used to protect the electronic components of circuit board 4122. Thus, although the functionality of the plastic shield 4130 is as described above, plastic protective shield 4130 is provided with a pyramidal protrusion or extrusion 4130A with a slot 4130AA through which the vertical PCB 4300 can extend. Pyramidal extrusion 4130A also facilitates alignment of vertical PCB 4300 to enable easier interface with the connector 4310 for a CCM 4110 or LAM 4120 depending on the arrangement of LAMs 4120 and CCM 4110 in the data logger 4100.

CCM 4110 of FIGS. 78 and 79 is further not provided with an additional circuit board 140A as used in the CCM 110 of FIGS. 16(a) and 17(b) as the CCM 4110 typically accommodates components such as top LEDs and other components on CCM circuit board 4140. The same electrical connections can be made as for the previously described embodiments.

In some embodiments, Power over Ethernet (POE) may be used as a power source for each embodiment of the data logger 100, 3100 and 4100. A separate PoE module, in one embodiment having the same form factor as LAM 120, 3120, 4120 described above, may be provided to act as PoE module (though it would have the same or similar functionality as the CCM 110, 3110 described above). This, compared to a 9-30 v industrial power supply, allows use of a very wide range of voltage according to new PoE standards, for example in the order of 20 v-52 v. Such an additional PoE LAM would desirably allow Ethernet TCP/IP communications with a cloud server. Further, as a PoE system may be assumed to have an uninterruptable power supply (UPS) at its source, batteries may not be required in a PoE auxiliary power module to provide resilience to power outages.

In convenient embodiments, the PoE module may have the same form factor as CCM 110, 3110 described above. Such a CCM may have Ethernet port (RJ-45) on the side, conveniently next to the USB and SD Card Flap.

### Example Embodiments of Data Logger Block 100

Data logger block 100, and its constituent LAM(s) 120 or CCM 110, may be used for a number of exemplary potential applications as follows:
(1) general purpose data logging and actuation, for example including:
   1× pair of differential analogue input terminals
   4× user configurable analogue input terminals;
   4× user configurable digital input or output terminals;
   5× user configurable power supply terminals (PWR); and
   5× dedicated ground terminals (GND)
(2) digital input and output logging and actuation, for example including:
   10× user configurable digital input or output or pulse width modulation;
   5× user configurable power supply terminals (PWR); and
   5× dedicated ground terminals (GND)
(3) analogue data logging, for example including:
   10× user configurable analogue input terminals:
   configured in pairs to be differential, or
   single ended analogue, or
   4-20 mA current loop
   5× configurable power supply terminals (PWR); and
   5× dedicated ground terminals (GND)
(4) differential analogue data logging, for example including:
   2× pairs of 2× differential analogue input terminals;
   6× configurable analogue input terminals:
   single ended analogue, or
   4-20 mA current loop
   5× user configurable power supply terminals (PWR); and
   5× dedicated ground terminals (GND)
(5) user configurable driver, for example driving up to a 2 Amps load, including for example:
   2× sets of 4× configurable pins to accommodate any combination of:
   2× stepper motor (which may utilise all 2× 4× sets of pins);
   4× DC motors (which may utilise pairs of pins); and
   8× relays (which may utilise a single pin, switching high or low)

A LAM 120 may also be provided with minimal components, for example excluding the microcontroller or other chips and/or using the LAM main circuit board 122 for performing the power and communications functions, simply to allow wiring in of power to the terminal block 126A and CAN communications up through spring connector(s) to a CCM 110. Even the spring connectors could be avoided if required to minimise cost. This embodiment may be used for interfacing with CCM(s) 110 including sensors.

### On Board Sensors

Data logger 100 may accommodate a range of sensor types as described above. In addition, CCM 110 or LAM(s) 120 may include on-board sensors with some examples being as follows:
(1) Vibration sensing unit, including a fast 2000 Hz 12 bit precision 3-axis accelerometer for vibration and motion detection; or
(2) Inertial Measurement Unit (IMU) including a 200 Hz 9 axis inertial measurement chipset for computing G-forces, orientation, heading and including a 3-axis accelerometer, a 3-axis gyroscope and a 3-axis magnetometer; or
(3) GPS Unit including precision GPS utilising GPS and GLONASS satellite systems; or
(4) Vehicle GPS and IMU Unit which contains the sensors for options (2) and (3) allowing fusion processing of:
precision positioning including dead reckoning;
G-forces;
Orientation;
Heading;
Motion gestures;
vehicular stopping, turning, bumps in road, corrugations

### Use of Data Logger Block 100

On deployment of data logger 100, a user is able to log or stream data points from sensors and actuators connected to, or included within, the data logger 100. For example, in the case of a plant reticulation system, a sensor might include a soil moisture sensor and the actuator a water flow valve or tap which can be turned on or off depending on sensed moisture in line with logic provided for the LAM microcontroller which can also perform any computations or transformations required.

Most conveniently, the sensed data logged to the memory storage device, such as a USB drive or SD card, on retrieval by opening sealing flap 195 and retrieving data from the USB drive or SD card from port 195A or 195B. The advantage of logging data to such memory storage is that it is not inhibited by the data rate of an available wireless network, as would be the case with data streaming or streamed off wirelessly. This allows very high data rate logging of sensor acquisitions and actuator end-points whereby the data at hand may take longer to transfer off the data logger 100 than acquiring the data. This may be advantageous to some users in very fast acting systems.

However, data can be streamed wirelessly from data logger 100 using, for example, a TCP/IP protocol. Such data loggers 100 may include all, or a combination of:
Wi-Fi communications, for example 802.11 bgn Wi-Fi communications at 10 MBps'
Cellular communications, for example including a cellular data chipset allowing data to be streamed from the data logger 100 by:
   GPRS;
   3G;
   4G; and
   Dedicated Cellular IoT bands:
   NB-IoT; and
   CAT-M1
LoRA for long range RF communications using ISM RF bands either point to point between devices in a system or acting as a base station to remote devices in a system and which may include a LoRA-WAN communications structure for interface with retail carriers; and
Satellite communications.

Data acquired from the memory storage device, such as the removable SD card, or wirelessly can then be processed using software, conveniently web hosted software, that allows the user to customise data processing to the data acquisition system they have constructed, for example for use in process control. Alternatively, a user may process acquired data within their own software, whether proprietary or ‘off the shelf’, for example through the Office platform.

A data logging system including the data logger block 100 as described above and allowing data processing through web hosted software would allow a user to, for example, build control systems based on state machines, as known in the art of process control, and to create and configure bespoke states, the operation of sensors and actuators within a state and the required transition logic between states appropriate to the process control system the user is building. AND/OR logic may be preferred as a transition logic.

A “state machine” is at least one but, more typically, a collection of states with each state being a configuration of user selected devices and end-points across one or more devices which may be included within a system or one or more sub-systems. An infinite number of state machines is possible and they are configured as a user wishes. For example, in water reticulation to a soil, devices may include a soil moisture sensor (with end-point soil moisture content) and a valve (actuator) for supplying water (with end point valve on or off) when soil moisture is below a determined set point. Two states would be:
Moisture above set point Water tap off
Moisture below set point Water tap on

It may be appreciated that the soil moisture sensor could efficiently be polled more frequently when the water valve is on to avoid water wastage and perhaps less frequently when the water valve is off, particularly if moisture content is at a level that the user knows is indicative of recent rainfall and which may be programmed into the state machine. A state machine may be much more complex than this simple example.

States can be transitioned between if thresholds on one or more end-points are achieved simultaneously within that state. Various different transitions to different states can be achieved if a different combination of thresholds is specified and simultaneously achieved.

Configuration of an end-point being a sensor may involve a question of how often to poll the sensor and what to do with the data (e.g. log it to internal memory and/or stream it to another device in the system or a connected server for remote logging and display of data).

Configuration of an end-point being an actuator may pass in input data, undertake some action on its actuator and configure what to do with the resulting output of data indicating undertaken (e.g. log it to internal memory and/or stream it to another device in the device in the system or a connected server for remote logging and display of data).

In embodiments, a state machine needs to be specified at the device level at minimum and can then optionally be specified at the sub-system and system levels as applicable to user requirements. A device level state machine takes precedence.

In exemplary embodiments, each state contains the configuration of:
Required
   Device Power Configuration
   Powered on and working
   Various levels of sleep configuration dependent on the device
   Communications per communication socket available to the device (i.e. each of, Bluetooth, LoRa, RS485, Wi-Fi, Cellular, Satellite)
   Allowing or disallowing communications from other devices (of the data logger system or a process control system using the data logger system and configuration of end-points
   Configuring a maximum data rate per communication socket
   Optionally allowing or disallowing end-points to stream data at configurable maximum rates per communication socket
Optional
   Specific configuration of end-points

In embodiments, a device functions as part of the data logger system when it is in a suitable power state, is connected via a socket and allows communications on that socket. An exemplary arrangement is shown in Figure

A state machine can be set up at a sub-system level, whereby one device in the system is allocated the position of Controller and other device(s) are Notifier(s) as shown in Figures.

A ‘Controller’ then holds a state machine and issues tasks to device(s) in the sub-system according to the state machine.

A ‘Notifier’ undertakes tasks and notifies the Controller if the task has been achieved.

A ‘task’ may include a configuration of end-points with the addition of assessment of the end-point data against various thresholds. In embodiments, at a minimum, a Notifier will report to a Controller if a threshold is achieved in a flip flop fashion, minimising the network overhead for communication of the task.

If a combination of thresholds are achieved by the Notifiers being given tasks by the controller, then the controller may cancel the tasks on the Notifiers, change to the next state and issue new tasks to the Notifiers depending on the thresholds required to exit this new state and transition to another state, and the end-point configuration setup across the devices.

A data logging system as described above may advantageously create a highly autonomous system of logging and control whilst minimising the network overhead which can be low data rate limited and high latency, often associated with low power remote low cost electronic devices. Such a data logging system facilitates ‘edge computing’ whereby minimum communication is required to maximise the required outcome of the data logging system (or a process control system based upon it) from a user perspective.

The data logging system advantageously includes a server and web user interface which allows configuration and visualisation of the data logging system, necessary state machines for inclusion and calculations to be performed, through transformations, on acquired signal and actuator data. State machines can be stored as a script created by machine code or by a graphical user interface, for example the web user interface. The web user interface may be accessed through a web app. Alternatively, or additionally, configuration and visualisation may be enabled through native mobile app.

The server can then house the state machine scripts in a database and allow writing, updating and downloading of that configuration to devices in the field by means of TCP connection to a remotely connected device via a gateway or via a Bluetooth® connected device via means of a mobile phone application or a Bluetooth® enabled internet connected computer. In particularly preferred embodiments, the data logger 100, 3100, 4100 is provided with Bluetooth functionality. Such script can also be downloaded and transferred to a LAM or CCM, for example by downloading on to an SD card and plugging this SD card into the LAM SD card port.

Backend software is provided to take this configuration and turn it into files readable by the system controller firmware.

The Backend software also allows the live bi-directional interaction between a data logger block 100, 3100, 4100 that is connected to the internet by way of TCP/IP or through a Bluetooth proxy (phone with Bluetooth connection to Cranio system and internet). The Backend software contains sub-systems for logging sensor and actuating data to a database as well as forwarding such streamed data to the internet via a suitable web based application such as Web Sockets. Retrospective lookup of data within the database is conveniently enabled by a backend RESTful API. Routing of data between end-points (each end-point being a sensor, actuator or transformation of data from sensors and/or actuators) that are not located on the same local network is enabled through a backend software routing system, allowing data logging systems to span the wider internet.

Advantageously, the data logging system includes the ability to request data saved to the system flash memory(s) for a specific time period. Given that data logger blocks 100 are able to interact with their sensors/actuators/end-points faster than they can be polled and streamed to the web hosted database, it is advantageous to be able to request the high speed data for a particular time period, even if the offloading of this data takes a long time.

This feature is usually enabled by a combination of transformations and streaming of a ‘lower speed’ data end-point to the web hosted backend database, indicating an event happened. The user would configure a transformation to indicate an event or logical “TRUE FALSE” expression which could be a much lower data rate than the raw end-point of interest. On reviewing the data and sighting the slower speed event data, the user can then request the high-speed data around that event providing unique value to the user.

The data logger system may also provide ‘dashboard(s)’ in the form of visualisations of end-point data being optionally forwarded to the server by a user selected device or sub-system, as above described.

Within the configuration of a state (of a state machine), each end-point configuration may optionally be configured to forward its data to the server at a separately configurable rate to that of the underlying polling of the end-point. If forwarded to the server, the end-point data may conveniently be saved in a server database (or cloud) for historical lookup and can also be retrospectively and live viewed on the dashboard for the device or sub-system.

Dashboards may comprise ‘widgets’ which indicate end-point data or can act as end-points which may physically reside on the server to be used by a data logger system state machine. Widgets may include buttons, sliders, input fields, charts, graphs, dials, indicators and custom graphical elements indicating the end-point or output of data from an end-point (for example graphical representation of an end point such as a rotational position of a stepper motor or needle of a dial). A user can configure a dashboard comprising various widgets, according to user preference, with configuration and position on a page within the web browser as described above or native mobile application for each device and sub-system.

Such a data logging system conveniently allows edge computing by way of a ‘transformation’ system. Transformations are mathematical or logical functions configured on a device, such as a sensor actuator, to convert end-point data into a new data output. Transformations are performed in embodiments of the data logger system by a LAM microcontroller.

A transformation can be configured by the user in the same way as an end-point, for example an actuator end-point. The transformation may take in data from one or more end-points local to a device associated with that end-point and which may be local to that end-point. Data may be taken in at a user configurable interval (i.e every n data points from end-point X) and compute it into a new end-point which may be treated in the same as other end-points.

If a transformation end-point is configured by a state machine, its underlying end-points may conveniently inherit the required configuration to achieve the desired data output rate (which may be matched with the network speed). Tasks can be issued by a controller to a transformation end-point and be assessed and treated like any other end-point.

Transformations may be computed at set time intervals, or on each new sensor data point acquisition, as defined by the user. This allows the transformation of raw data to meaningful process information about the user's application, as well as creation of logical expressions allowing the detection of ‘events’. Such events can be used in the process control strategy within a state machine, or can be provided over the internet by way of data streaming using a wireless protocol, as described above, only if required. In this way, computer processing power can also be modularised with computer processing resources additional to those on-board the data logger 100, 3100, 4100 user device (such as a personal computer or tablet) can be accessed when appropriate.

A data logger system of embodiments of the invention comprises the following components, each described above:
Server
System or Sub-System of Devices
   Individual devices
   Wired or wireless sub-systems which act as a gateway to the server.
Each Device, System or Sub-System of Devices has the following:
   End-points
   Transformations
   State Machine
   Dashboard(s)

Each device needs to be configured with a state machine that defines its end-point configurations and any tasks to report to a larger sub-system.

A system of devices extends from single devices, sub-systems of communicating devices and a server.

Devices can only communicate with a server if they are connected to the internet. This is done by a device that has serial socket(s) allowing both serial communications and internet connectivity through at least one connection to the internet. Such a device is known as a gateway. A gateway can be a mobile phone or personal computer (tablet, laptop etc.) or a data logger, as described above, and connected to the server via serial and Wi-Fi, cellular or satellite connection.

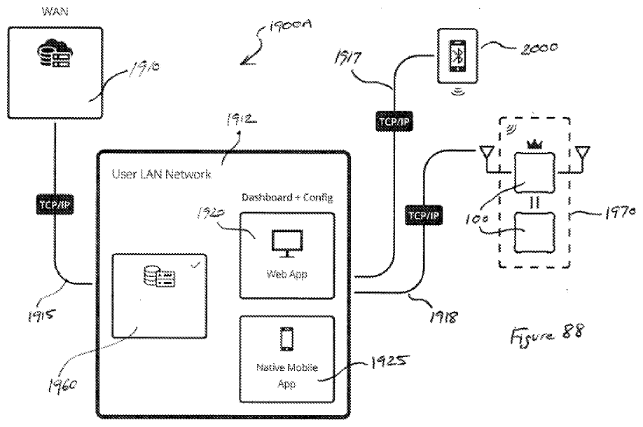

Referring to FIGS. 85 to 89, there are shown a number of data logger system block diagrams that shown the flexibility of use and configuration of data logger 100.

FIG. 85 shows a system 1800 with server 1810 forming part of a wide area network (WAN) with a direct internet connection 1816 to a single device 1850, in this embodiment, a smartphone 2000 with Bluetooth functionality. The range of Bluetooth, at say 10 m, allows a user of the smartphone 2000 to configure data logger 100 as indicated in the diagram and receive data, conveniently as transformed by transformations as described above. Dashboard(s) and desired ‘widgets’ (for example as described above) may be provided on the smartphone 2000 to enable ready visualisation of data and transformations whether in real time or retrospectively following data download. It will be appreciated that devices are not limited to smartphones but can be any computing device or an IoT device. Widgets can also be end-points in their own right interacting with devices within system 1800. Some exemplary widgets are described below with reference to FIG. 95.

Server 1810, which in embodiments is provided by a third party service provider and which is conveniently cloud based, also has an internet connection 1815 to a user LAN network 1812 which also provides dashboard(s) 1830 as described above, conveniently in the same form as displayed on smartphone 2000 though further transformations of the data could be conducted within the user LAN network 1812, if required. The user LAN network may include web app 1820 and native mobile app 1825 for allowing configuration and visualisation of data logger 100. Web app 1820 and native mobile app 1825 are available from the third party service provider. However, such configuration is transferred to the smartphone 2000 via server 1810 and on to data logger 100. In alternative embodiments, a user could download the configuration to an SD card or USB and transfer directly to data logger 100. This option may be more convenient where the user is physically close to the data logger 100.

In this embodiment, the server 1810 may enable data hosting by the third party service provider.

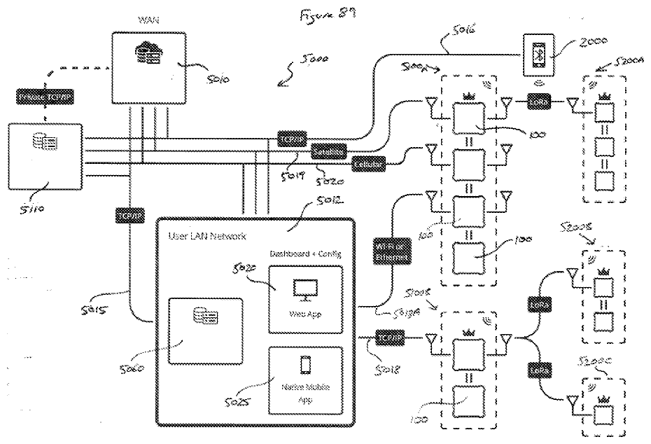

FIG. 86 shows an alternative system 1800A for allowing configuration of data logger 100 by a single device, again a Bluetooth enabled smartphone 2000 via user server 1860 rather than third party server 1810. System 1800A differs from system 1800 of FIG. 85 by limiting the role of the third party server 1810 to downloads of new software available for configuration of data logger 100A. Otherwise, the necessary software and firmware—as well as data from data logger 100—is hosted on the user's own server 1860 within the user LAN network 1812A. It will be understood that cloud hosting is also possible. As such, internet connection 1817 with the smartphone 2000 is sufficient to enable configuration of the data logger 100A. There is no requirement for the configuration data—again input through web app 1820 or native mobile app 1825—to be transferred to data logger 100A via server 1810.

FIG. 87 shows a more complex embodiment where, in contrast to systems 1800, 1800A of FIGS. 85 and 86, system 1900 includes a system 1970 comprising a plurality of data loggers 100. As with system 1800 of FIG. 85 and system 1800A of FIG. 86, configuration is possible through the user's LAN network 1912, in particular server 1960, using web app 1920 or native mobile app 1925 available from the server 1910 of the third party service provider, for example through internet connection 1915. Server 1910 has respective internet connections 1916 and 1917 to device system 1950 (here comprising a single smartphone 2000) and system 1970. Smartphone 2000 is also available for transfer of configuration for the data loggers 100 of system 1970, conveniently by Bluetooth protocol. Data is hosted on the server 1910 of the third party service provider. In alternative embodiments, system 1970 may comprise a plurality of devices, not limited necessarily to data loggers 100. Other computing devices or IoT devices could be used instead. Further, system 1970 may be a sub-system of a more complex system.

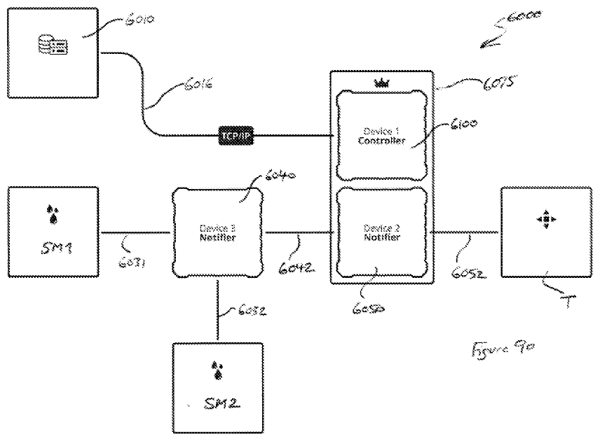

FIG. 88 shows a system 1900A with the user server 1960 being used in the same manner as described above for user server 1860 and the component reference numerals are the same with the prefix “19”. User LAN network 1912 has respective internet connections 1917 and 1918 to both system 1970 and smartphone 2000 and system 1970. The configuration of data loggers 100 in system 1970 can be achieved either via smartphone 2000 or directly by the user without use of an intermediating device.

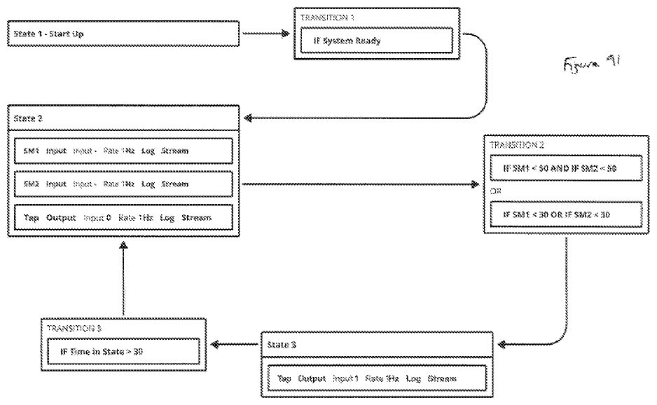

FIG. 89 shows a complex system 5000 comprising the third party server 5010, again cloud based in this embodiment, and its wide area network as well as a further cloud SAAS server 5110.

SAAS server 5110 may be an additional hosted cloud server by a third party provider that has dedicated resources for use by the system 5000. Instead of the user using the available cloud server 5010 (potentially at no cost), or hosting their own server on suitable computer hardware and network 5060, a third party provider can host this server 5110 with dedicated resources above those available from server 5010. This ensures data integrity, security, and increased resources for data storage, computation requirements of streaming large volumes of data and even cloud resources that could be used for post processing of data such as machine learning or artificial intelligence in further embodiments.

SaaS server 5110 allows the user to access a server with more resources than the free third party server 5010 avoiding the potential complexity involved with deployment and maintenance of such resources on the user server 5060.

System 5000 may include a plurality of gateways 5100A and 5100B comprising a plurality of data loggers 100 as described above. As gateways 5100A and 5100B allow communications, via LoRA protocol to tertiary systems 5200A and 5200B each comprising a plurality of data loggers 100. This arrangement is particularly suitable where components of the system are remotely located from each other. Gateways 5100A and 5100B, as well as tertiary systems 5200A and 5200B may also be enabled to communicate with each other.

Device 2000, again a smartphone in this embodiment, may allow configuration of gateways 5100A and 5100B and tertiary systems 5200A and 5200B through Bluetooth protocol, if in range. However, the configuration may also be done through the user LAN network 5012 and its server 5060 which has Wi-Fi or Ethernet connection 5018A to gateway 5100A and an internet connection 5018 to gateway 5100B. Third party server 5010 serves the same function as a source of updates to system software and firmware though in the conceptual system 5000 could also be used for hosting data.

Additional functionality in system 5000 allows cloud hosting of system data in a Software as a Service (Saas) option which can be more cost effective than hosting on third party service provider server 5010 or the user's own server 5060 as described above. The cloud server 5110 has a private internet connection to server 5010. Both servers 5010 and 5110 are shown as having respective internet connection 5016, satellite connection 5019 and cellular connection 5020 to gateway 5100A and onward connections, via LoRA protocol to tertiary system 5200A. These connections are also available to the user LAN network 5012. However, a wide range of connection options are possible.

It will be understood that, in conceptual system 5000, configuration of the gateways 5100A, 5100B and tertiary systems 5200A and 5200B can be done either via the service provider servers 5010 and 5110 or user server 5060 using web app 5020 or native mobile app 5025. In embodiments, a user can interact with a plurality of different servers allowing different functionality, typically dependent on user credentials. It is also possible to have different devices and/or systems linked to different servers, typically by authenticated transfer of responsibility to or between particular servers be they servers 5010, 5060 and 5110 or other server configurations.

Referring to FIG. 95, there are shown a number of possibilities allowing user visualisation of system data. Examples only of the available widgets are line graphs 8010, bar charts 8020, gauge charts 8030, stacked bar charts 8040 which may cover a number of systems and pie charts 8060. Visualisation may be provided for a particular time period, for example a date range as indicated in calendar 8070. Other exemplary widgets would include dials, numeric Output fields, Text Output fields, Numeric Input fields, Text Input fields and slider Input fields but there are many options and some could be user configurable.

FIG. 95 also shows a specific graphical input widget 8050 for a stepper motor allowing a number of steps turned left or right, or number of degrees turn, or absolute position turn. Such widgets could be configured for other end-points forming part of a user system.

Each output widget can visualise data streamed to the backend server via live stream, or by retrospective lookup of data streamed to the database. Each input widget acts as any other end-point in the system and can be configured in the same way as other endpoints.

### SYSTEM EXAMPLES

### Example 1

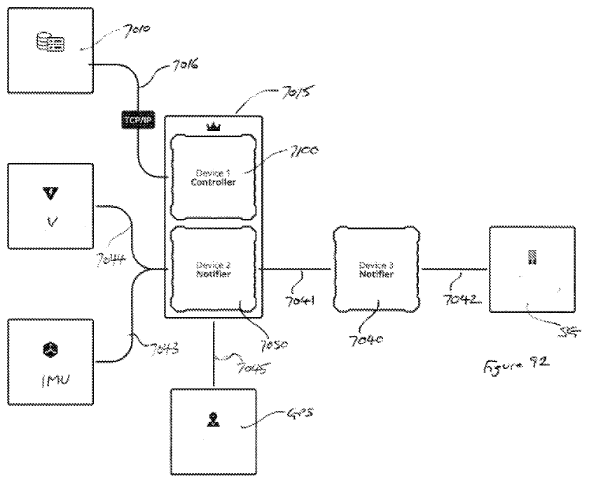

FIG. 90 shows a block diagram for a water reticulation system 6000 convenient for watering plants in a garden or horticultural setting. Water reticulation system 6000 comprises two soil moisture sensors SM1 and SM2 as well as a tap T. Tap T supplies water when the state of SM1 and SM2 show a lower than acceptable soil moisture levels. System 6000 includes a user server 6010 which allows configuration of the component devices of the system and has—for that purpose—an internet connection 6016 to a control module 6075 and a system of devices. In turn, control module 6075 includes a controller device 6100 (first device) and a notifier device 6050 (second device), each having the configuration of data logger 4100 as described above. Control module 6075 has connection 6042 to a further device 6040 acting as a notifier for ‘harvesting’ soil moisture signals from soil moisture sensors SM1 and SM2 through respective connections 6031 and 6032. When notifier 6040 indicates to control module 6075—through connection 6042—that soil moisture is low, and potentially only then to reduce data transmission requirements through the system, controller 6100 initiates a control response. Controller 6100 causes notifier 6050 to alter its state from Tap T off to Tap T on. That task is communicated to Tap T through connection 6052.

System 6000 achieves efficient reticulation through a simple logic and three transitions as described below with reference to FIG. 91. The first state (State 1) is start up of system 6000 which transitions (Transition 1) to an “If system ready state” (first transition). Soil moisture sensors SM1 and SM2 sense moisture at a sampling rate of 1 Hz with tap T off in State 2. It will be understood that a different sampling rate can be adopted.

State 2 continues unless Transition 2 is triggered. In the embodiment shown, Transition 2 is triggered if SM1 and SM2 indicate to notifier 6040 that their values are simultaneously <50% or less than 30% at any point in time. Under those conditions, notifier 6040 informs control module 6075 accordingly and controller 6100 informs notifier 6050 of the corresponding task, i.e. to turn tap T on. The system 6000 enters state 3 with tap T being turned on and its running state being monitored also at 1 Hz via notifier 6050. The system 6000 here allows a dwell time because soil moisture below a certain level will require a certain amount of time to rectify it. Here, that time has arbitrarily been set at 30 seconds (though this will depend on a number of factors not discussed here).

When time of tap T on is greater than 30 seconds system 6000 transitions (Transition 3) to State 2 by turning tap off (again indicated by notifier 6050) and monitoring soil moisture again.

During operation of the system, data is harvested at each of the devices ready for download when required by the user. The data does not require to be streamed back to the user server 6010 during operation of the system 6000. That is, the system 6000 is not constrained by streaming speeds over a network through connection 6016.

### Example 2

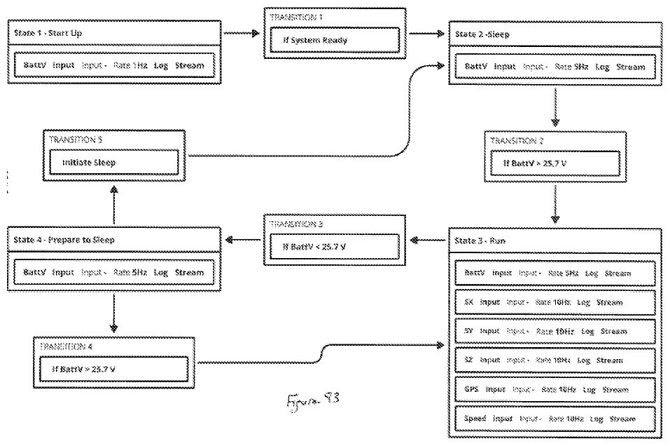

FIG. 92 shows a block diagram for an electric vehicle control system 7000 with configuration similar to that shown in FIG. 90. However, electric vehicle control system 7000 comprises a battery voltage sensor V and a GPS sensor (GPS) and a strain gauge (SG) as well as the electric vehicle inertial management unit (IMU). SG is used to monitor force acting on the electric vehicle chassis currently under development.

IMU operates the electric vehicle subject to signals as received from the battery voltage sensor V, the GPS sensor and the strain gauge. System 7000 includes a user server 7010 which allows configuration of the component devices of the system and has—for that purpose—an internet connection 7016 to a control module 7075 and a system of devices. In turn, control module 7075 includes a controller device 7100 (first device) and a notifier device 7050 (second device), each having the configuration of data logger 4100 as described above. Control module 7075 has connection 7042 to a further device 7040 acting as a notifier for ‘harvesting’ signals (SX, SY, SZ) from strain gauge SG.

Notifier 7050 harvests signals from the IMU, battery voltage sensor V and GPS sensor through respective connections 7043, 7044 and 7045. The voltage signal from battery voltage sensor V can be regarded as a primary control parameter and is described further below. Dependent on signals harvested via notifier 7050, controller 7100 sets tasks for the IMU to operate the electric vehicle through connection 7043. In embodiments, the controller 7100 may set tasks for the electric vehicle when in a stationary state.

System 7000 achieves efficient operation of the electric vehicle through a state machine having simple logic and four transitions as described below with reference to FIG. 93. The first state (State 1) is start up of system 7000 which transitions (Transition 1) to an “If system ready state” and on to a ‘sleep’ state (state 2) where battery voltage sensor V monitors voltage (at sampling rate 5 Hz) with sleep state being maintained and task for IMU unchanged if battery voltage <25.7 v. It will be understood that a different sampling rate can be adopted.

State 2 continues, in the embodiment shown, unless Transition 2 is triggered where battery voltage sensor detects battery voltage >25.7 v. Under those conditions, notifier 7050 informs controller 7100 and controller 7100 in turn informs notifier 7050 of the corresponding task, i.e. to run the electric vehicle under control of the IMU. The system 7000 enters state 3 with the IMU running to operate the electric vehicle. In state 3, sensor signals from battery voltage sensor V, GPS, an additional speed input (not shown in the block diagram) and strain gauge (AX, AY, AZ) are sampled with 10 Hz sampling rate for each signal other than battery voltage sensor V which is sampled at 5 Hz. These sampling rates are selectable by the user.

If at any time, battery voltage V sensor detects a battery voltage below 25.7 v, due to the vehicle stopping for example, system 7000 transitions (transition 3) to a prepare to sleep state (state 4). Battery voltage is monitored for a selected time (sampling rate 5 Hz). If battery voltage remains below 25.7 v, the system 7000 transitions (transition 5) to ‘initiate sleep’ and back to sleep state 2. On the other hand, if battery voltage becomes greater than 25.7 v, system 7000 transitions (transition 4) back to the run state.

During operation of the system, data is harvested at each of the devices ready for download when required by the user. The data does not require to be streamed back to the user server 7010 during operation of the system 7000. That is, the system 7000 is not constrained by streaming speeds over a network through connection 7016.

Structuring a data logging and processing system in this way, addresses the issue that networking between devices is often a bottleneck for a data acquisition and processing system. In contrast, data logger block 100 can interface with sensors and actuators at extremely high data rates, sometimes being in the order of 1000's of times per second. The ability to acquire sensor and actuator data at these high rates as well as provide control feedback at this rate is advantageous. Sending out sensor and actuator data via a network encounters data rate limitations as well as latency. Allowing the data logger block 100 to log and control, through its microcontroller(s) (and if necessary any ancillary microprocessor(s)), its connected sensors and actuators at a data rate uninhibited by an associated but optionally used network provides an advantage, usually only provided by much more expensive and complex systems than that described here.

The expected user involvement with the data logging system using data logger blocks 100 will be:
a) The user configures their data logging system for the first time.
b) The user logs or streams all data points from their various sensors and actuators connected to data logger block 100 to the backend software for retrospective detailed analysis within the web based user interface. Streaming is one option. Another option is to download data, for example from an SD card to which data has been stored at a fast sampling rate (i.e. greater than available internet speed), and download it to the user or third party server for visualization through dashboards as described above. This avoids streaming of data and need for internet connection, simplifying the system set up.
c) On assessment, the user will create calculations on logged sensor or actuator signal data that provides meaningful information about the user's application (for example a process control system for watering plants) without the need for streaming the high speed raw data, or retrospective review of the data.
d) The user may validate that their transformations are indeed giving them the desired outcome or event detection.
e) The user may then look to decrease the streaming of high speed samples, and even the logging of high speed samples to further optimise the data logging system, or associated process control system, for power consumption or further improved speed etc.
f) The user may also choose to add other data logger blocks (or LAMs in some instances) to the data logging system to insights provided by the system to the user, at which time the above process may be iterated to further improve it.

Such a data logging system provides value to the user by providing a complete IoT platform for enabling electronic devices to sense and actuate as fast as they can without the limitations of a network. Such a data logging system also facilitates the iterative process of IoT system refinement through fit for purpose data investigation tools and configuration of the device in the same web or native app interface.

Modifications and variations to the data logger and data logging system described in this specification may be apparent to the skilled reader of this disclosure. Such modifications and variations are deemed within the scope of the present invention.

Throughout this specification, unless the context requires otherwise, the word “comprise” or variations such as “comprises” or “comprising”, will be understood to imply the inclusion of a stated integer or group of integers but not the exclusion of any other integer or group of integers.

1-47. (canceled)

48. A data logger comprising:
a plurality of self-supported and directly interconnected modules comprising:
at least one module, acting as a logging and/or actuating module (LAM), having a housing including a sensor interface for connecting at least one sensor and at least one actuator to the data logger, said housing enclosing a circuit board and a microcontroller mounted on said circuit board to process signals received from said sensor interface, said LAM module including at least one memory storage device for storing data received as input from said sensor interface, said at least one memory storage device being removable from said at least one LAM module to enable downloading of data; and
at least one module, acting as a control and communications module (CCM), having a housing directly connected to and closing said at least one LAM module and a controller for controlling operation of the data logger and hosting a state machine for controlling operation of said at least one actuator,
wherein the housing of said at least one LAM module is directly electrically and mechanically connected to the housing of an adjacent LAM or CCM module through complementary connectors formed or accommodated within the adjacent LAM or CCM modules; and
wherein signals from said sensor interface are processable by the microcontroller onboard each LAM module using transformations determined by a user of the data logger for controlling operation of said at least one actuator through the state machine.

49. The data logger of claim 48, wherein a logging and/or actuation module (LAM) is directly connected to at least one further LAM to form a stack of LAMs.

50. The data logger of any one of the preceding claims, wherein LAMs of the same or different data loggers are networked by way of serial communications over a wireless network, wherein said serial communications are provided by a protocol selected from the group consisting of a short range protocol, a long range protocol (preferably LoRA) and TCP/IP.

51. The data logger of claim 50, allowing serial communications with a user device selected from the group consisting of a mobile phone, smartphone, tablet, portable and computing device.

52. The data logger of claim 51, comprising at least one user configurable input and at least one user configurable output as selected by a user of the data logger.

53. The data logger of claim 52, including a plurality of memory storage devices, a port being provided for each memory storage device within each LAM of the data logger.

54. The data logger of claim 53, wherein the data logger stores data at a faster rate than streaming of data externally from the data logger through an available wireless network.

55. The data logger of any one of the preceding claims comprising a plurality of power supplies selected from the group comprising an industrial power supply, battery power supply, a power supply based on energy harvesting and a power supply that enables data and power to be transferred simultaneously.

56. The data logger of claim 55, wherein said power supply includes a primary power supply and at least one auxiliary power module, wherein a LAM is configured as said at least one auxiliary power module; and wherein, where multiple auxiliary power modules are used, the CCM enables negotiation between the multiple auxiliary power modules via serial communications to determine which auxiliary power module provides power to the data logger.

57. The data logger of any one of the preceding claims, wherein said at least one sensor or actuator is connected to a housing of the data logger with a connection providing at least an IP67 rating for the data logger, wherein said at least one sensor or actuator is connected to a housing comprised within the data logger by a clamping seal for a sensor or actuator cable, said seal sealing ingress along a path of said cable and forming a clamp preventing said cable being pulled out of said housing.

58. The data logger of claim 57, wherein said clamping seal is provided within a wall of said housing by pinching of the sensor or actuator cable internally of the wall.

59. The data logger of claim 48, wherein a protective shield is located above said circuit board.

60. A data logger system comprising:
at least one sensor;
at least one data logger comprising:
a plurality of self-supported and directly interconnected modules comprising:
at least one module, acting as a logging and/or actuating module (LAM), having a housing including a sensor interface for connecting at least one sensor and at least one actuator to the data logger, said housing enclosing a circuit board and a microcontroller mounted on said circuit board to process signals received from said sensor interface, said LAM module including at least one memory storage device for storing data received as input from said sensor interface, said at least one memory storage device being removable from said at least one LAM module to enable downloading of data;
at least one module, acting as a control and communications module (CCM), having a housing directly connected to and closing said at least one LAM module and a controller for controlling operation of the data logger and hosting a state machine for controlling operation of the data logger and hosting a state machine for controlling operation of said at least one actuator,
wherein the housing of said at least one LAM module is directly electrically and mechanically connected to the housing of an adjacent LAM or CCM module through complementary connectors formed or accommodated within the adjacent LAM or CCM modules; and
wherein signals from said sensor interface are processable by the microcontroller onboard each LAM module using transformations determined by a user of the data logger for controlling operation of said at least one actuator through the state machine,
wherein said at least one data logger communicates with a process control unit, wherein at least one actuator is controllable by the process control unit in response to signals received from said at least one sensor and logged by the data logger.

61. The data logger system of claim 60, wherein sampling rate of said sensor input is set by a user, said sampling rate being set by a user through at least one of a web user interface, a mobile app and a script placed on said memory storage device, said sampling rate of said sensor input being greater than an available wireless communications network speed.

62. A data logger system as claimed in claim 61, further comprising:
a server communicable with said data logger;
wherein said server enables a user to configure said data logger.

63. The data logger system of claim 62, wherein said server communicates with a user accessible memory for storing data, data from said data logger being stored in said user accessible memory.

64. The data logger system of claim 62, wherein said server is communicable with a user network for download of software and firmware to operate said data logger and a user configures said data logger via said user network.

65. The data logger system of claim 62, wherein said server is communicable with cloud based memory for storage of data from said data logger.

66. The data logger system of claim 62, configured for edge computing.

67. A data logger comprising:
a plurality of modules comprising:
at least one module, acting as a logging and/or actuating module (LAM), having a housing including a sensor interface for connecting at least one sensor or actuator to the data logger, each LAM module integrating at least one input and at least one output for each said at least one sensor or actuator; and
at least one module, acting as a control and communications module (CCM), having a housing directly connected to said at least one LAM module and comprising a controller for controlling operation of the data logger,
a user accessible memory for storing data received as input from said sensor interface, said user accessible memory being at least partly comprised in said at least one LAM module,
wherein the housing of said at least one LAM module is directly electrically and mechanically connectable to the housing of an adjacent LAM or CCM module through complementary connectors formed or accommodated within the adjacent modules, each LAM module being configured for storing, receiving and processing signals received from its sensor interface; and
wherein signals from said sensor interface are processable onboard each LAM module using transformations determined by a user of the data.
